(19) United States
(12) Patent Application Publication
(10) Pub. No.: US 2026/0018491 A1
(43) Pub. Date: Jan. 15, 2026

(54) SEMICONDUCTOR MODULE AND VEHICLE

(71) Applicant: Rohm Co., Ltd., Kyoto-shi (JP)

(72) Inventor: Shoya WATANABE, Kyoto-shi (JP)

(21) Appl. No.: 19/335,436

(22) Filed: Sep. 22, 2025

Related U.S. Application Data
(63) Continuation of application No. PCT/JP2024/009538, filed on Mar. 12, 2024.

(30) Foreign Application Priority Data
Mar. 28, 2023 (JP) 2023-052008

(51) Int. Cl. H01L 23/473; B60L 15/20; H01L 25/07; H10D 80/20

(52) U.S. Cl. CPC H01L 23/473; H01L 25/072; H10D 80/215; H10D 80/251; B60L 15/20

(57) ABSTRACT

A semiconductor module includes a cooler, a plurality of semiconductor devices, and a capacitor. The cooler includes a housing having a receiving portion and a hollow portion that is disposed externally around the receiving portion as viewed in a first direction. The housing has a first surface, a second surface, and a third surface on which the plurality of semiconductor devices are respectively mounted. Each of the first surface, the second surface, and the third surface faces away from the receiving portion with respect to the hollow portion in a direction orthogonal to the first direction. The first surface, the second surface and the third surface each have a different normal direction. At least a part of the capacitor is housed in the receiving portion.

### TECHNICAL FIELD

The present disclosure relates to a semiconductor module and a vehicle.

### BACKGROUND ART

WO-A-2017/094370 discloses an example of a semiconductor module including a cooler. The cooler has a housing having a hollow area and a heat dissipation body. The housing has an opening communicating with the hollow area. The heat dissipation body is attached to the housing so as to close the opening. A part of the heat dissipation body is housed in the hollow area. A semiconductor device is bonded to a part of the heat dissipation body that extends outward from the hollow area. When a refrigerant flows down the hollow area, the refrigerant contacts the heat dissipation body. This allows the semiconductor device to be cooled through the heat dissipation body.

The semiconductor module disclosed in WO-A-2017/094370 has a relatively large size. Therefore, it is desirable to further reduce the overall size of the semiconductor module including a cooler.

### BRIEF DESCRIPTION OF THE DRAWINGS

FIG. 1 is a perspective view of a semiconductor module according to a first embodiment of the present disclosure.

FIG. 2 is a perspective view of a cooler in the semiconductor module shown in FIG. 1.

FIG. 3 is a plan view of the cooler shown in FIG. 2.

FIG. 4 is a right-side view of the cooler shown in FIG. 2.

FIG. 5 is a back view of the cooler shown in FIG. 2.

FIG. 6 is a cross-sectional view taken along a line VI-VI of FIG. 3.

FIG. 7 is a cross-sectional view taken along a line VII-VII of FIG. 3.

FIG. 8 is a cross-sectional view taken along a line VIII-VIII of FIG. 3.

FIG. 9 is a cross-sectional view taken along a line IX-IX of FIG. 3.

FIG. 10 is a cross-sectional view taken along a line X-X of FIG. 5.

FIG. 11 is a plan view of one of semiconductor devices in the semiconductor module shown in FIG. 1.

FIG. 12 is a plan view corresponding to FIG. 11, in which the sealing resin is shown transparently.

FIG. 13 is a partially enlarged plan view of FIG. 12.

FIG. 14 is a plan view corresponding to FIG. 11, in which the first conductive member is shown transparently and the sealing resin and the second conductive member are omitted.

FIG. 15 is a right-side view of the semiconductor device shown in FIG. 11.

FIG. 16 is a bottom view of the semiconductor device shown in FIG. 11.

FIG. 17 is a cross-sectional view taken along a line XVII-XVII of FIG. 12.

FIG. 18 is a cross-sectional view taken along a line XVIII-XVIII of FIG. 12.

FIG. 19 is a partially enlarged view of the first element and its surrounding area shown in FIG. 18.

FIG. 20 is a partially enlarged view of the second element and its surrounding area shown in FIG. 18.

FIG. 21 is a cross-sectional view taken along a line XXI-XXI of FIG. 12.

FIG. 22 is a cross-sectional view taken along a line XXII-XXII of FIG. 12.

FIG. 23 is a plan view of the semiconductor module shown in FIG. 1

FIG. 24 is a front view of the semiconductor module shown in FIG. 1.

FIG. 25 is a back view of the semiconductor module shown in FIG. 1.

FIG. 26 is a bottom view of the semiconductor module shown in FIG. 1.

FIG. 27 is a cross-sectional view taken along a line XXVII-XXVII of FIG. 23.

FIG. 28 is a cross-sectional view taken along a line XXVIII-XXVIII of FIG. 23.

FIG. 29 is a cross-sectional view taken along a line XXIX-XXIX of FIG. 24.

FIG. 30 is a diagram of a vehicle in which the semiconductor module of FIG. 1 is mounted.

FIG. 31 is a right-side view of a cooler in a semiconductor module according to a second embodiment of the present disclosure.

FIG. 32 is a back view of the cooler shown in FIG. 31.

FIG. 33 is a back view of the semiconductor module according to the second embodiment of the present disclosure.

FIG. 34 shows a plan view of a cooler in a semiconductor module according to a third embodiment of the present disclosure.

FIG. 35 is a cross-sectional view taken along a line XXXV-XXXV of FIG. 34.

FIG. 36 is a cross-sectional view taken along a line XXXVI-XXXVI of FIG. 34.

FIG. 37 is a cross-sectional view of the semiconductor module according to the third embodiment of the present disclosure.

FIG. 38 is a back view of a semiconductor module according to a fourth embodiment of the present disclosure.

FIG. 39 is a cross-sectional view of the semiconductor module shown in FIG. 38.

FIG. 40 is a cross-sectional view of the semiconductor module shown in FIG. 38, wherein the cross-sectional position is different from that in FIG. 39.

FIG. 41 is a plan view of a semiconductor module according to a fifth embodiment of the present disclosure.

FIG. 42 is a cross-sectional view taken along a line XLII-XLII of FIG. 41.

FIG. 43 is a cross-sectional view taken along a line XLII-XLIII of FIG. 41.

FIG. 44 is a plan view of a semiconductor module according to a sixth embodiment of the present disclosure.

FIG. 45 is a back view of the semiconductor module shown in FIG. 44.

### DETAILED DESCRIPTION OF EMBODIMENTS

The following describes preferred embodiments of the present disclosure in detail with reference to the drawings.

### First Embodiment

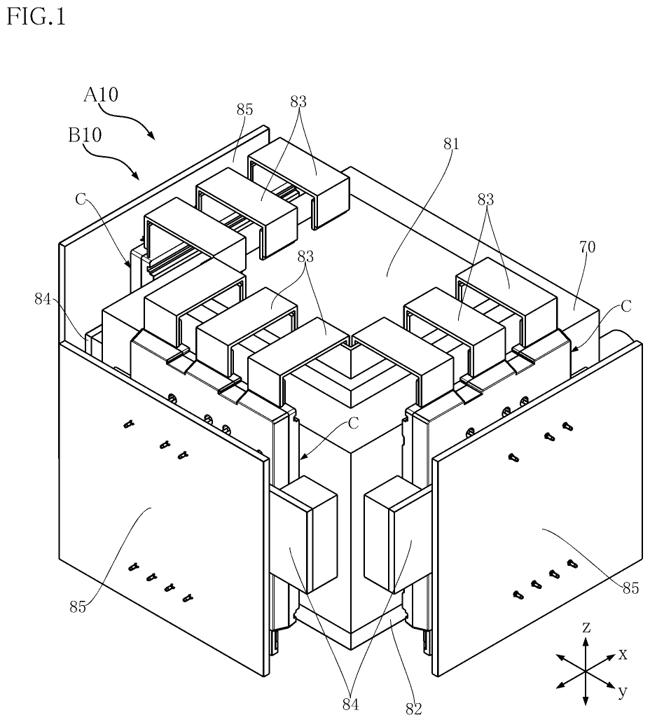

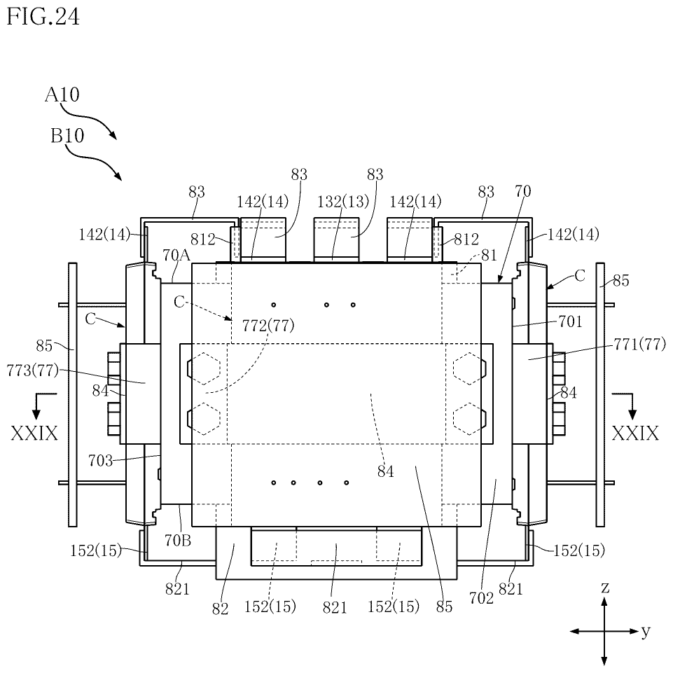

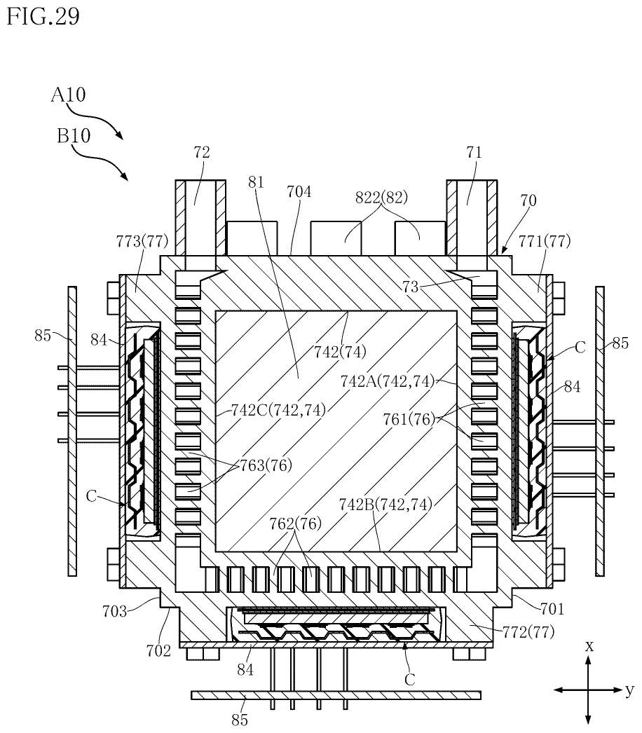

Based on FIGS. 1 to 29, a semiconductor module A10 according to a first embodiment of the present disclosure will be described. The semiconductor module A10 converts direct current power into alternating current power. The semiconductor module A10 constitutes a part of a power conversion circuit, such as an inverter. As shown in FIG. 1, the semiconductor module A10 comprises a cooler B10, a capacitor 81, a current sensor 82, a plurality of busbars 83, a plurality of attachment members 84, and a plurality of wiring boards 85.

In the explanation of the semiconductor module A10, for the sake of convenience, the normal direction of the obverse surface 70A of the housing 70 of the cooler B10, which will be described later, is referred to as a “first direction z”. One direction orthogonal to the first direction z is referred to as a “second direction x”. A direction orthogonal to the first direction z and the second direction x is referred to as a “third direction y”.

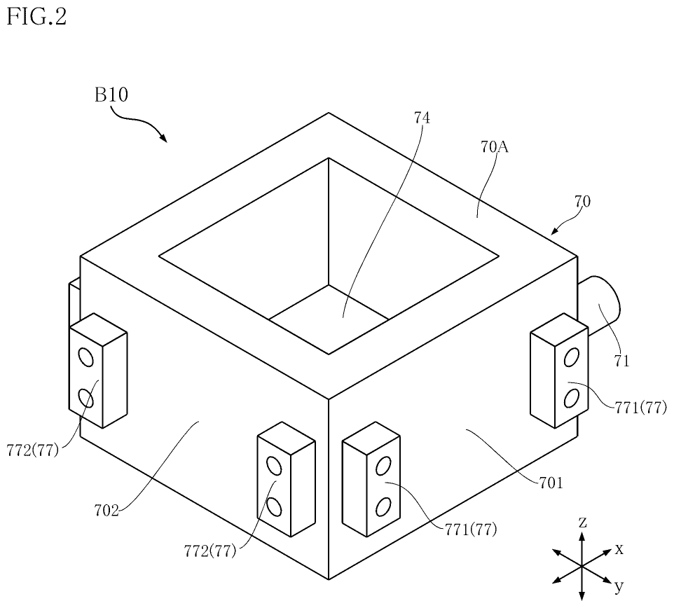

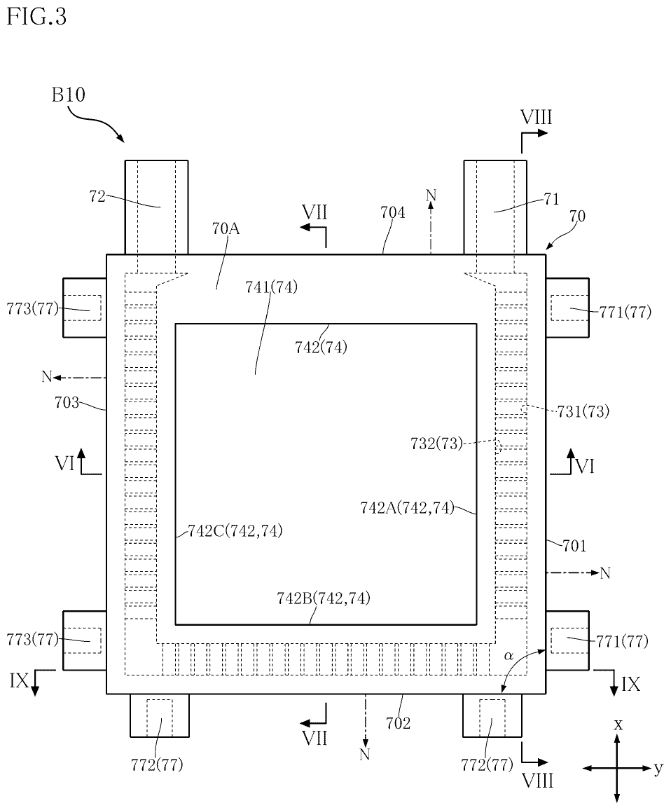

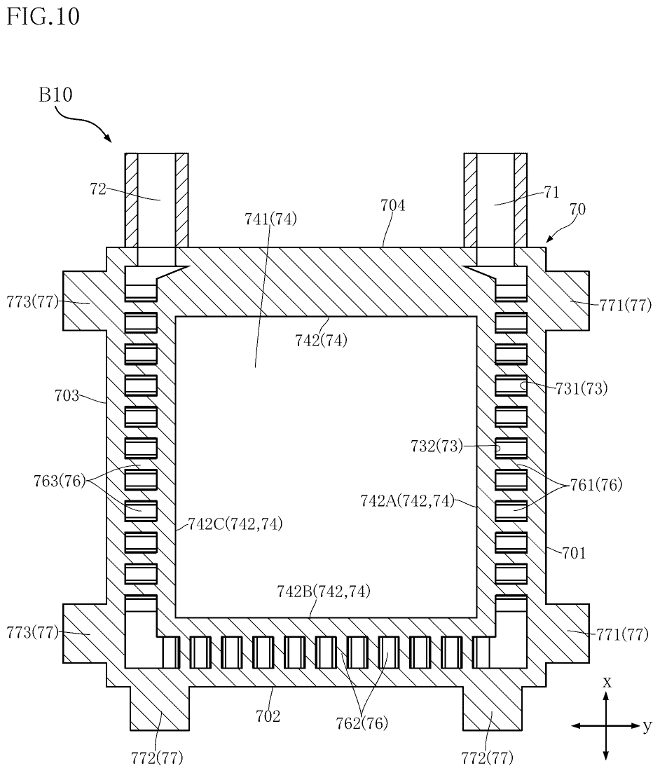

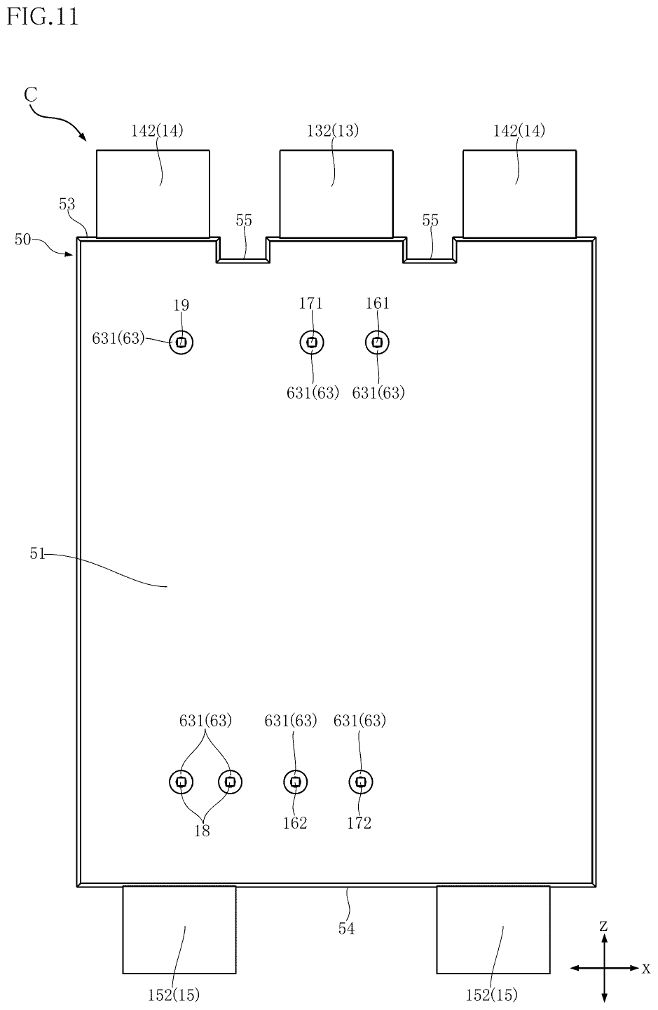

First, the configuration of the cooler B10 included in the semiconductor module A10 will be described based on FIGS. 2 to 10. As shown in FIGS. 3 and 10, the cooler B10 comprises a housing 70, a plurality of heat dissipation bodies 76, and a plurality of attachment portions 77.

The housing 70 is rectangular as viewed in the first direction z, as shown in FIGS. 2 and 3. The housing 70 is made of a material containing metal. The metal includes, for example, aluminum (Al). As shown in FIGS. 3 to 7, the housing 70 has an obverse surface 70A, a reverse surface 70B, a first surface 701, a second surface 702, a third surface 703, a fourth surface 704, an inlet 71, an outlet 72, a hollow portion 73, a receiving portion 74 and a recess 75.

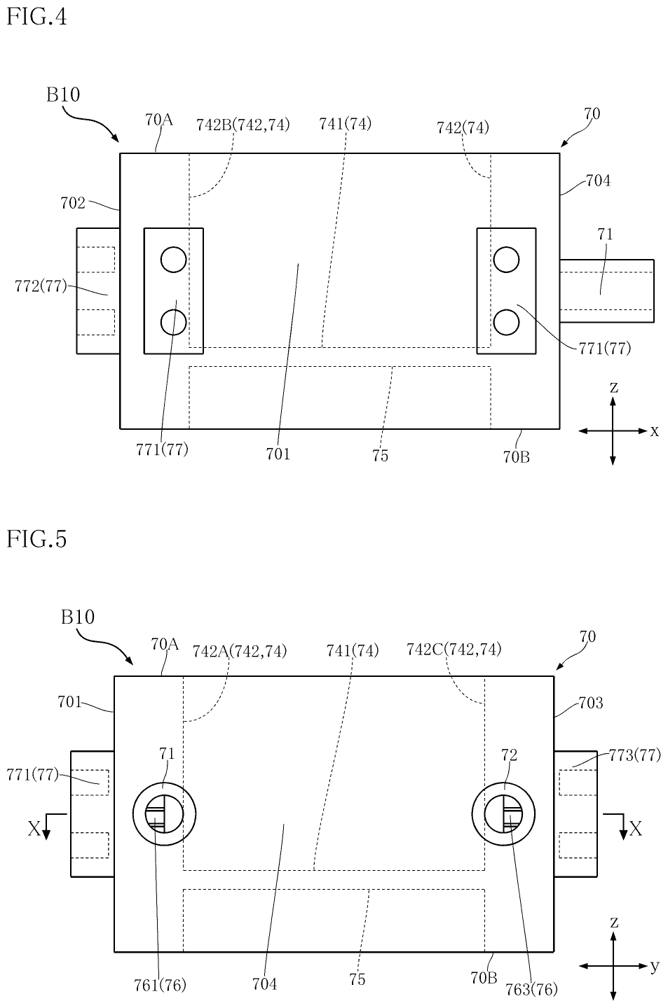

As shown in FIGS. 4 and 5, the obverse surface 70A and the reverse surface 70B face away from each other in the first direction z. As viewed in the first direction z, each of the obverse surface 70A and the reverse surface 70B has a frame-like shape. As shown in FIG. 3, the first surface 701, the second surface 702, the third surface 703, and the fourth surface 704 face away from the receiving portion 74 with respect to the hollow portion 73 in a direction orthogonal to the first direction z. In the semiconductor module A10, the first surface 701 and the third surface 703 face away from each other in the third direction y. The second surface 702 and the fourth surface 704 face away from each other in the second direction x. The first surface 701, the second surface 702, the third surface 703 and the fourth surface 704 each have a different normal direction N.

As shown in FIG. 3, the second surface 702 is located between the first surface 701 and the third surface 703. The second surface 702 is adjacent to each of the first surface 701 and the third surface 703. The first surface 701 and the second surface 702 form an internal angle α as viewed in the first direction z. In the semiconductor module A10, the internal angle α is 90 degrees. The fourth surface 704 is located on the side opposite to the second surface 702 with respect to the first surface 701.

As shown in FIGS. 2 and 4 to 7, the receiving portion 74 is recessed from the obverse surface 70A. The receiving portion 74 has an opening on the obverse surface 70A.

As shown in FIGS. 3 to 7, the housing 70 has an intermediate surface 741 and an inner circumferential surface 742. The intermediate surface 741 and the inner circumferential surface 742 define the receiving portion 74. The intermediate surface 741 faces the same side as the obverse surface 70A in the first direction z. The intermediate surface 741 is located between the obverse surface 70A and the reverse surface 70B in the first direction z. The intermediate surface 741 is located closer to the reverse surface 70B than the obverse surface 70A. The inner circumferential surface 742 faces a direction orthogonal to the first direction z. The inner circumferential surface 742 includes a first area 742A, a second area 742B, and a third area 742C. The first area 742A faces away from the first surface 701 in the third direction y. The second area 742B faces away from the second surface 702 in the second direction x. The third area 742C faces away from the third surface 703 in the second direction x.

As shown in FIGS. 3, 6, 7 and 10, the hollow portion 73 is disposed externally around the receiving portion 74 as viewed in the first direction z. During use of the semiconductor module A10, refrigerant flows down the hollow portion 73. The housing 70 has a first peripheral surface 731 and a second peripheral surface 732. The first peripheral surface 731 and the second peripheral surface 732 define the hollow portion 73. The first peripheral surface 731 and the second peripheral surface 732 face each other in a direction orthogonal to the first direction z. The second peripheral surface 732 is located between the first peripheral surface 731 and the inner circumferential surface 742 defining the receiving portion 74.

As shown in FIGS. 3, 5 and 10, the inlet 71 and the outlet 72 are provided on the fourth surface 704. Each of the inlet 71 and the outlet 72 is cylindrical, extending along the second direction x. The inlet 71 and the outlet 72 each communicate with the hollow portion 73. The inlet 71 is located closer to the first surface 701 than the outlet 72. The outlet 72 is located closer to the third surface 703 than the inlet 71. Refrigerant is poured through the inlet 71, flows down the hollow portion 73 and is discharged from the outlet 72. As viewed in the first direction z, the refrigerant flows in one direction in the hollow portion 73 around the receiving portion 74. In the semiconductor module A10, in the first direction z, the inlet 71 has a center that is aligned with a center of the outlet 72.

As shown in FIGS. 4 to 7, the recess 75 is recessed from the reverse surface 70B of the housing 70. The recess 75 is located on one side of the first direction z of the receiving portion 74 (the side toward which the reverse surface 70B faces in the first direction z).

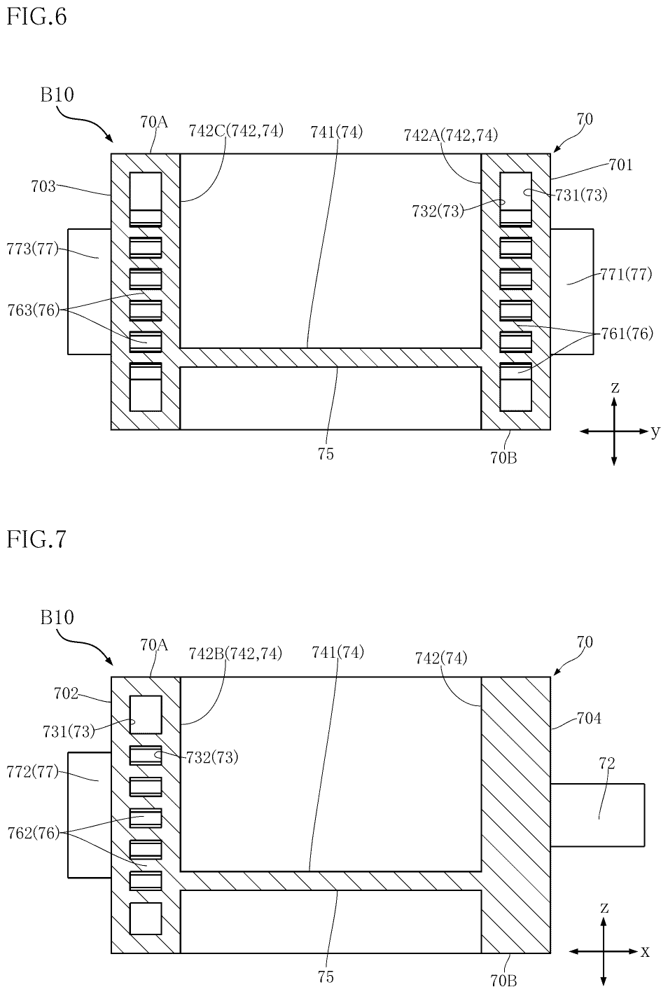

The heat dissipation bodies 76 are accommodated in the hollow portion 73 as shown in FIGS. 6 to 10. Each of the heat dissipation bodies 76 is connected to the first peripheral surface 731 and the second peripheral surface 732 that define the hollow portion 73. In the semiconductor module A10, each of the heat dissipation bodies 76 has a pin-like shape. However, the shape of each of the heat dissipation bodies 76 is not limited thereto. The heat dissipation bodies 76 are made of the same metal material as the housing 70, for example.

As shown in FIGS. 6, 7, and 10, the heat dissipation bodies 76 respectively overlap with the first surface 701, the second surface 702, and the third surface 703 as viewed in a direction orthogonal to the first direction z. The heat dissipation bodies 76 include a first heat dissipation body 761, a second heat dissipation body 762, and a third heat dissipation body 763. The first heat dissipation body 761 is connected to an area of the first peripheral surface 731 that faces away from the first surface 701 in the third direction y. The second heat dissipation body 762 is connected to an area of the first peripheral surface 731 that faces away from the second surface 702 in the second direction x. The third heat dissipation body 763 is connected to an area of the first peripheral surface 731 that faces away from the third surface 703 in the third direction y.

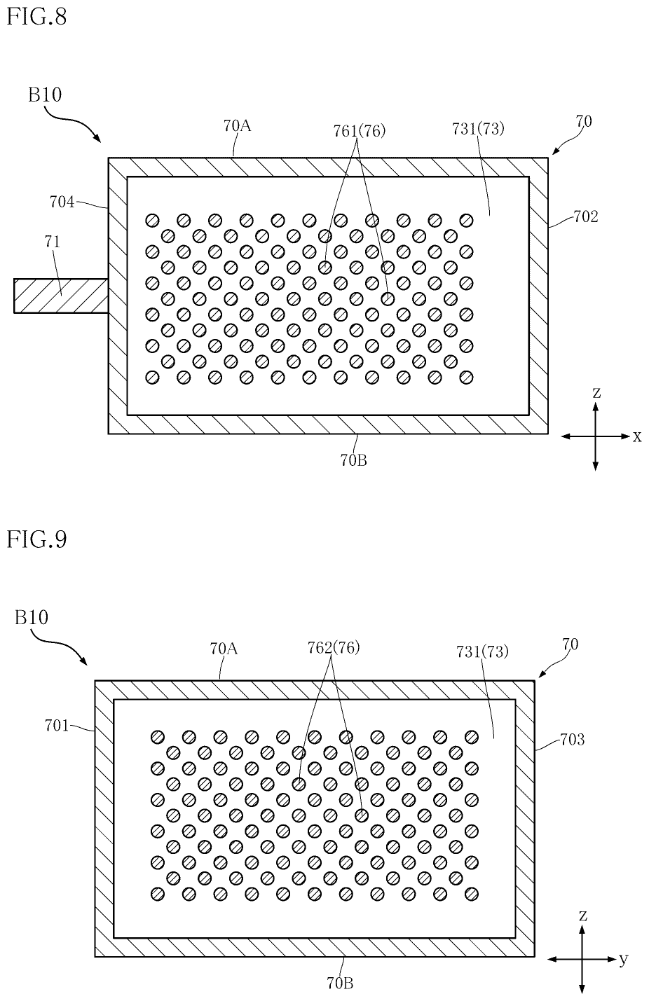

As shown in FIGS. 8 and 9, in the semiconductor module A10, the second heat dissipation body 762 has a surface area equal to a surface area of the first heat dissipation body 761. The third heat dissipation body 763 has a surface area equal to a surface area of each of the first heat dissipation body 761 and the second heat dissipation body 762.

The attachment portions 77 are provided respectively on the first surface 701, the second surface 702, and the third surface 703, as shown in FIG. 3. The attachment portions 77 are made of the same metal material as the housing 70, for example. The attachment portions 77 include a first attachment portion 771, a second attachment portion 772, and a third attachment portion 773.

The first attachment portion 771 is provided on the first surface 701, as shown in FIG. 3. The first attachment portion 771 protrudes from the first surface 701 in the third direction y. The first attachment portion 771 includes two portions spaced apart from each other in the second direction x. The second attachment portion 772 is provided on the second surface 702. The second attachment portion 772 protrudes from the second surface 702 in the second direction x. The second attachment portion 772 includes two portions spaced apart from each other in the third direction y. The third attachment portion 773 is provided on the third surface 703. The third attachment portion 773 protrudes from the third surface 703 in the second direction x. The third attachment portion 773 includes two portions spaced apart from each other in the second direction x.

Next, the configuration of the semiconductor devices C included in the semiconductor module A10 will be described based on FIGS. 11 to 22. The semiconductor devices C are identical to each other. Thus, the following explanation will focus on one of the semiconductor devices C.

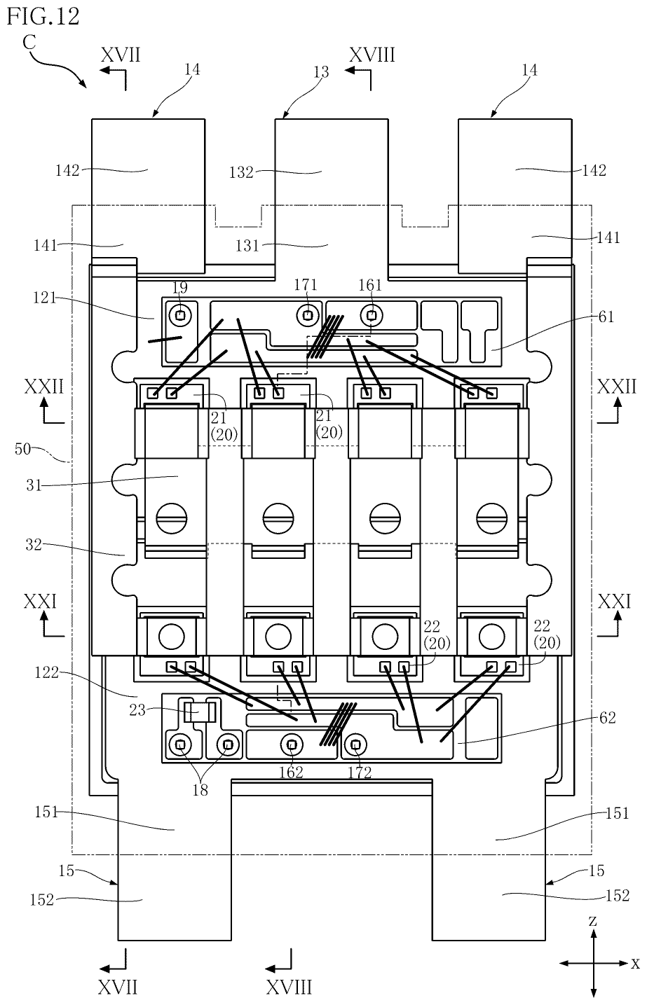

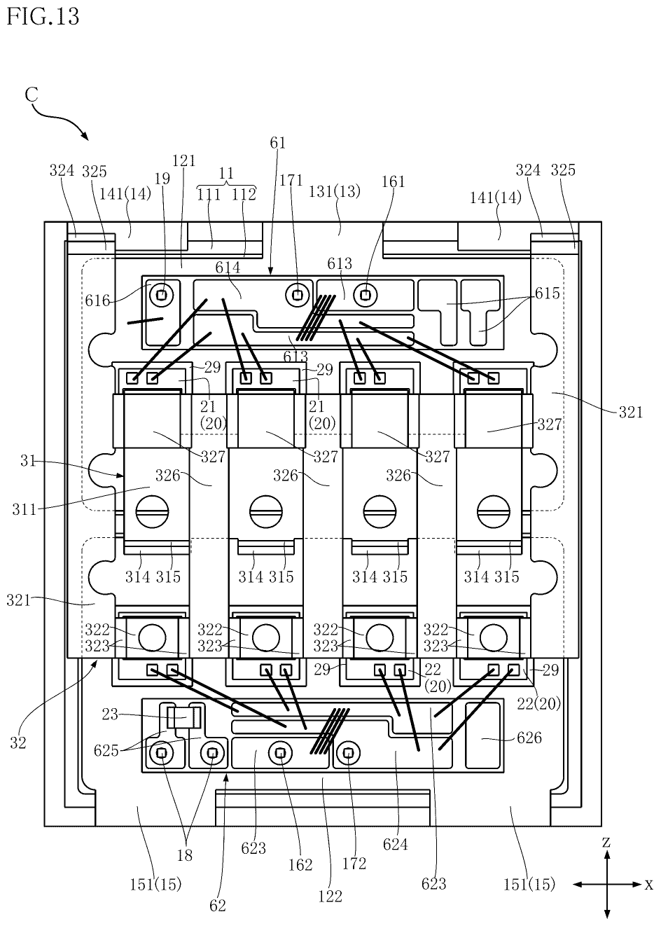

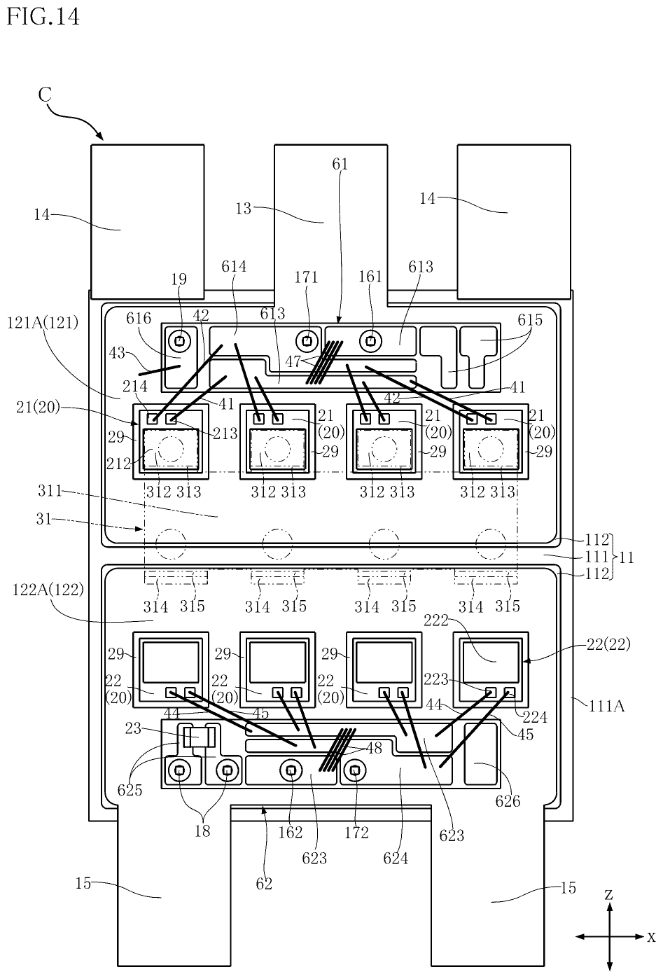

The semiconductor device C has a base material 11, a first conductive layer 121, a second conductive layer 122, a first power terminal 13, two second power terminals 14, two third power terminals 15, a first signal terminal 161, a second signal terminal 162, a plurality of semiconductor elements 20, a first conductive member 31, a second conductive member 32, and a sealing resin 50. Furthermore, the semiconductor device C includes a third signal terminal 171, a fourth signal terminal 172, two fifth signal terminals 18, a sixth signal terminal 19, a thermistor 23, a first wiring 61, and a second wiring 62. In FIGS. 12 and 13, the sealing resin 50 is shown transparently for the sake of understanding. In FIG. 12, the sealing resin 50 seen through is shown as imaginary lines (double-dotted lines). In FIG. 14, for the sake of understanding, the first conductive member 31 is shown transparently, with the second conductive member 32 and the sealing resin 50 omitted.

The semiconductor device C converts DC power received at the first power terminal 13 and the two second power terminals 14 into AC power through the semiconductor elements 20. The converted AC power is output from each of the two third power terminals 15.

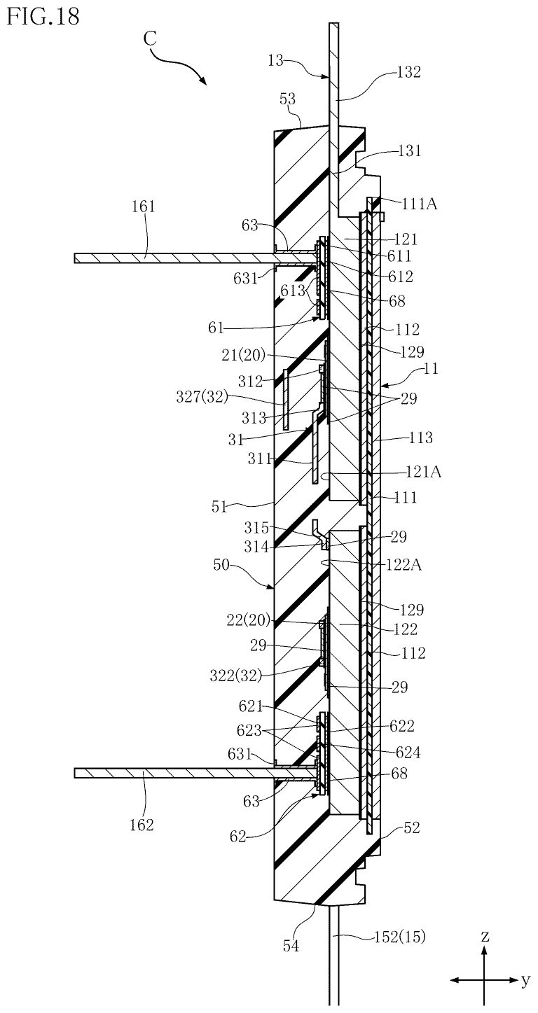

The base material 11 is located on the side opposite to the semiconductor elements 20 with respect to the first conductive layer 121 and the second conductive layer 122 in the third direction y, as shown in FIGS. 18 to 20. The base material 11 supports the first conductive layer 121 and the second conductive layer 122. In the semiconductor device C, the base material 11 is constituted of a DBC (Direct Bonded Copper) substrate. As shown in FIGS. 18 to 20, the base material 11 includes an insulative layer 111, two intermediate layers 112, and a heat dissipation layer 113. The base material 11 is covered with the sealing resin 50 except for a part of the heat dissipation layer 113.

The insulative layer 111 includes a portion interposed between the intermediate layers 112 and the heat dissipation layer 113 in the third direction y, as shown in FIGS. 18 to 20. The insulative layer 111 is made of a material with relatively high thermal conductivity. For example, the insulative layer 111 is made of a ceramic containing aluminum nitride (AlN). The insulative layer 111 may alternatively be formed from an insulating resin sheet instead of ceramics. The insulative layer 111 has a dimension in the third direction y that is smaller than a dimension in the third direction y of each of the first conductive layer 121 and the second conductive layer 122.

The two intermediate layers 112 are located between the insulative layer 111 and both of the first conductive layer 121 and the second conductive layer 122 in the third direction y, as shown in FIGS. 18 to 20. The intermediate layers 112 are spaced apart from each other in the first direction z. The intermediate layers 112 contain copper (Cu). As shown in FIG. 14, as viewed in the third direction y, the intermediate layer 112 is surrounded by a peripheral edge 111A of the insulative layer 111.

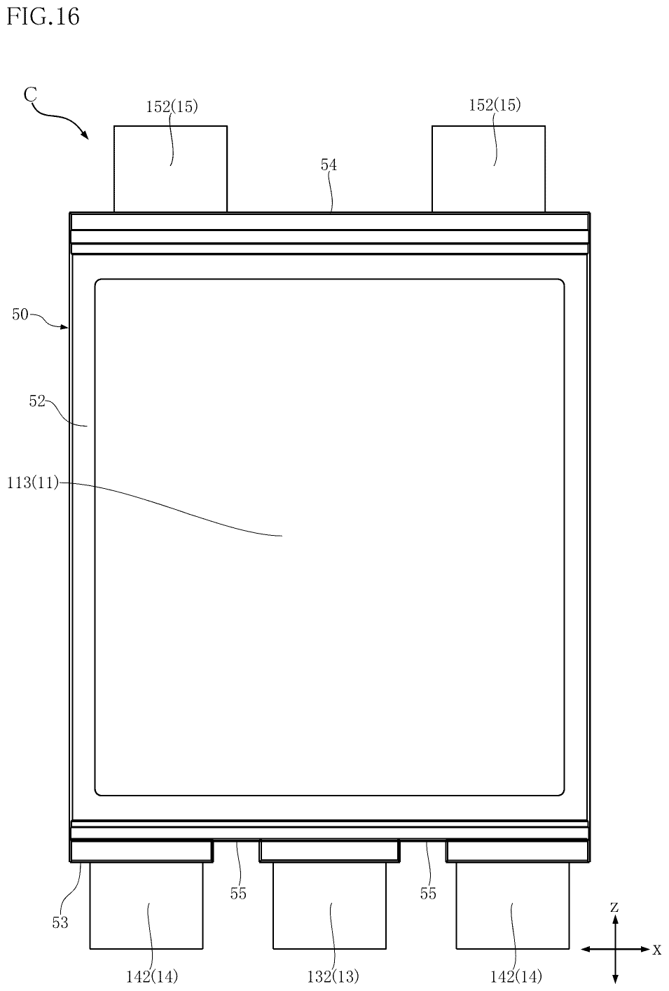

The heat dissipation layer 113 is located on the side opposite to the two intermediate layers 112 with respect to the insulative layer 111 in the third direction y, as shown in FIGS. 18 to 20. As shown in FIG. 16, the heat dissipation layer 113 is exposed from the sealing resin 50. The heat dissipation layer 113 contains copper. The heat dissipation layer 113 has a thickness greater than a thickness of the insulative layer 111. As viewed in the third direction y, the heat dissipation layer 113 is surrounded by the peripheral edge 111A of the insulative layer 111.

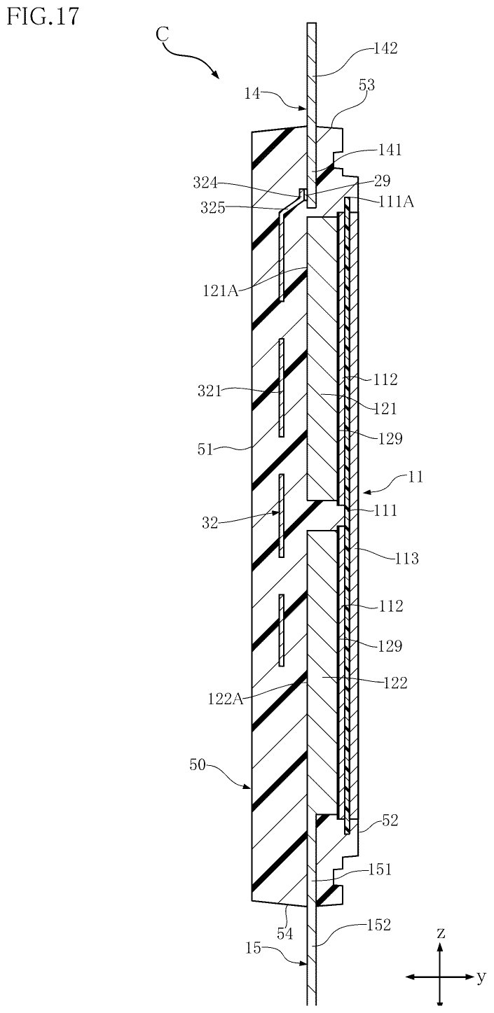

The heat dissipation layer 113 has a base surface 113A and a plurality of recessed portions 113B, as shown in FIG. 16. The base surface 113A faces away from the insulative layer 111 in the third direction y, as shown in FIGS. 17 to 22. In the third direction y, the base surface 113A is located on the side away from the sealing resin 50 with respect to a bottom surface 52 of the sealing resin 50, which will be described later. Hence, the base surface 113A protrudes from the sealing resin 50 in the third direction y. Each of the recessed portions 113B is recessed from the base surface 113A in the third direction y.

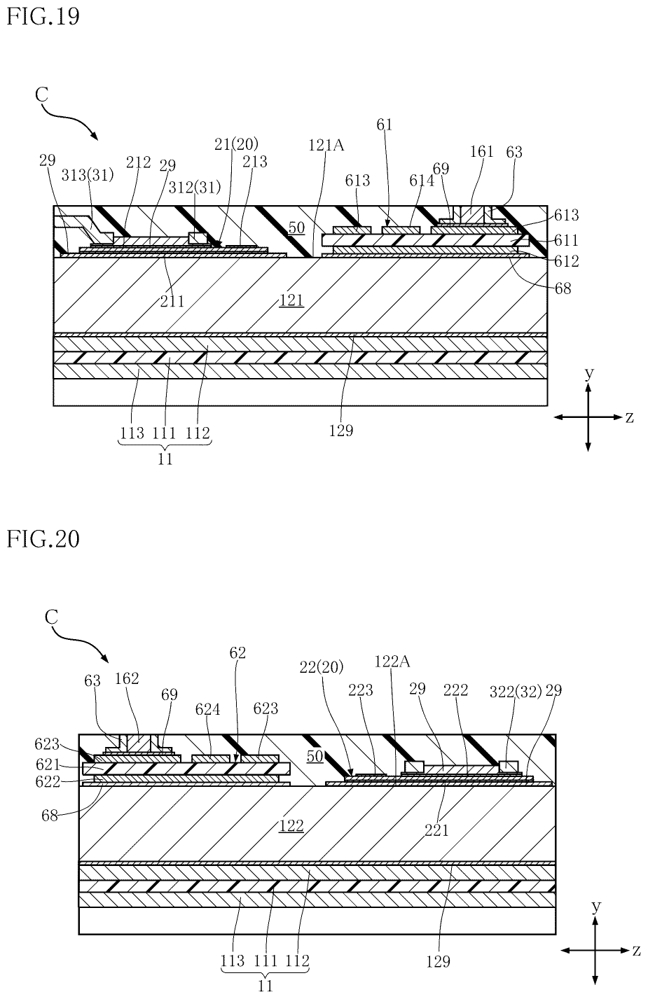

The first conductive layer 121 and the second conductive layer 122 are bonded to the base material 11, as shown in FIGS. 18 to 20. The first conductive layer 121 and the second conductive layer 122 contain copper. The first conductive layer 121 and the second conductive layer 122 are spaced apart from each other in the first direction z. As shown in FIGS. 17 and 18, the first conductive layer 121 has a first obverse surface 121A facing the third direction y. The first obverse surface 121A faces the semiconductor elements 20. As shown in FIG. 19, the first conductive layer 121 is bonded to one of the two intermediate layers 112 via the first bonding layer 129. The first bonding layer 129 is solder, for example. As shown in FIGS. 17 and 18, the second conductive layer 122 has a second obverse surface 122A facing the same side as the first obverse surface 121A in the third direction y. As shown in FIG. 20, the second conductive layer 122 is bonded to the other intermediate layer 112 among the two intermediate layers 112 via the first bonding layer 129.

Each of the semiconductor elements 20 is mounted on one of the first conductive layer 121 and the second conductive layer 122, as shown in FIGS. 14 and 18. The semiconductor elements 20 are, for example, MOSFETs (Metal-Oxide-Semiconductor Field-Effect Transistors). Alternatively, the semiconductor elements 20 may be switching elements such as IGBTs (Insulated Gate Bipolar Transistors) or diodes. In the explanation of the semiconductor device C, the semiconductor elements 20 assumed to be n-channel MOSFETs with a vertical structure. The semiconductor elements 20 include a compound semiconductor substrate. The compound semiconductor substrate contains silicon carbide (SiC).

As shown in FIG. 14, in the semiconductor device C, the semiconductor elements 20 include a plurality of first semiconductor elements 21 and a plurality of second semiconductor elements 22. The structure of each of the second semiconductor elements 22 is identical to that of each of the first semiconductor elements 21. The first semiconductor elements 21 are mounted on the first obverse surface 121A of the first conductive layer 121. The first semiconductor elements 21 are arranged along the second direction x. The second semiconductor elements 22 are mounted on the second obverse surface 122A of the second conductive layer 122. The second semiconductor elements 22 are arranged along the second direction x.

Each of the first semiconductor elements 21 has a first electrode 211, a second electrode 212, a first gate electrode 213 and a first detection electrode 214, as shown in FIGS. 14 and 19.

The first electrode 211 faces the first obverse surface 121A of the first conductive layer 121, as shown in FIG. 19. The first electrode 211 carries a current corresponding to the electric power before conversion of the first semiconductor element 21. In other words, the first electrode 211 corresponds to the drain electrode of the first semiconductor element 21. The first electrode 211 is conductively bonded to the first obverse surface 121A via the conductive bonding layer 29. As a result, the first electrode 211 of each of the first semiconductor elements 21 is electrically connected to the first conductive layer 121. The conductive bonding layer 29 is a sintered metal containing silver (Ag) or the like. Alternatively, the conductive bonding layer 29 may be solder.

As shown in FIG. 19, the second electrode 212 is located on the side opposite to the first obverse surface 121A of the first conductive layer 121 in the third direction y. Thus, the first electrode 211 is located on the side opposite to the second electrode 212 in the third direction y. The second electrode 212 carries a current corresponding to the electric power after conversion of the first semiconductor element 21. In other words, the second electrode 212 corresponds to the source electrode of the first semiconductor element 21.

The first gate electrode 213 is located on the side opposite to the first obverse surface 121A of the first conductive layer 121 in the third direction y, as shown in FIG. 19. Hence, the first gate electrode 213 is located on the same side as the second electrode 212 in the third direction y. The first gate electrode 213 receives a gate voltage to drive the first semiconductor element 21. As shown in FIG. 14, as viewed in the third direction y, the first gate electrode 213 has an area that is smaller than an area of the second electrode 212.

The first detection electrode 214 is located on the same side as the second electrode 212 and the first gate electrode 213 in the third direction y, as shown in FIG. 14. The first detection electrode 214 is located adjacent to the first gate electrode 213 in the second direction x. The first detection electrode 214 receives a voltage equivalent to the voltage applied to the second electrode 212. As viewed in the third direction y, the first detection electrode 214 has an area that is identical (or generally identical) to an area of the first gate electrode 213.

Each of the second semiconductor elements 22 has a third electrode 221, a fourth electrode 222, a second gate electrode 223 and a second detection electrode 224, as shown in FIGS. 14 and 20.

The third electrode 221 faces the second obverse surface 122A of the second conductive layer 122, as shown in FIG. 20. The third electrode 221 carries a current corresponding to the electric power before conversion of the second semiconductor element 22. In other words, the third electrode 221 corresponds to the drain electrode of the second semiconductor element 22. The third electrode 221 is conductively bonded to the second obverse surface 122A via the conductive bonding layer 29. As a result, the third electrode 221 of each of the second semiconductor elements 22 is electrically connected to the second conductive layer 122.

The fourth electrode 222 is located on the side opposite to the second obverse surface 122A of the second conductive layer 122 in the third direction y, as shown in FIG. 20. Hence, the third electrode 221 is located on the side opposite to the fourth electrode 222 in the third direction y. The fourth electrode 222 carries a current corresponding to the electric power after conversion of the second semiconductor element 22. In other words, the fourth electrode 222 corresponds to the source electrode of the second semiconductor element 22.

The second gate electrode 223 is located on the side opposite to the second obverse surface 122A of the second conductive layer 122 in the third direction y, as shown in FIG. 20. Hence, the second gate electrode 223 is located on the same side as the fourth electrode 222 in the third direction y. The second gate electrode 223 receives a gate voltage to drive the second semiconductor element 22. As shown in FIG. 14, as viewed in the third direction y, the second gate electrode 223 has an area that is smaller than an area of the fourth electrode 222.

The second detection electrode 224 is located on the same side as the fourth electrode 222 and the second gate electrode 223 in the third direction y, as shown in FIG. 14. The second detection electrode 224 is located on both sides of the second gate electrode 223 in the second direction x. The second detection electrode 224 receives a voltage equivalent to the voltage applied to the fourth electrode 222. As viewed in the third direction y, the second detection electrode 224 has an area identical to (or generally identical to) an area of the second gate electrode 223.

The first power terminal 13 is located on the side opposite to the second conductive layer 122 with respect to the first conductive layer 121 in the first direction z and is connected to the first conductive layer 121, as shown in FIGS. 12 and 18. As a result, the first power terminal 13 is electrically connected to the first electrodes 211 of each of the first semiconductor elements 21 via the first conductive layer 121. The first power terminal 13 is the P terminal (positive electrode) to receive the DC power to be converted. The first power terminal 13 extends from the first conductive layer 121 along the first direction z. The first power terminal 13 includes a covered portion 131 and an exposed portion 132. As shown in FIG. 18, the covered portion 131 is connected to the first conductive layer 121 and is covered with the sealing resin 50. The covered portion 131 is flush with the first obverse surface 121A of the first conductive layer 121. The exposed portion 132 extends from the covered portion 131 in the first direction z and is exposed externally from the sealing resin 50.

Each of the two second power terminals 14 is located on the same side as the first power terminal 13 with respect to the first conductive layer 121 and the second conductive layer 122 in the first direction z, and is spaced apart from the first conductive layer 121 and the second conductive layer 122, as shown in FIGS. 12 and 17. Each of the two second power terminals 14 is electrically connected to the fourth electrode 222 of each of the second semiconductor elements 22. The two second power terminals 14 are N terminals (negative electrodes) to receive the DC power to be converted. The second power terminals 14 are spaced apart from each other in the second direction x. Between the two second power terminals 14 in the second direction x is the first power terminal 13. Each of the two second power terminals 14 includes a covered portion 141 and an exposed portion 142. As shown in FIG. 17, the covered portion 141 is spaced apart from the first conductive layer 121 and is covered with the sealing resin 50. The exposed portion 142 extends from the covered portion 141 along the first direction z and is exposed externally from the sealing resin 50.

The two third power terminals 15 are located on the side opposite to the first conductive layer 121 with respect to the second conductive layer 122 in the first direction z and is connected to the second conductive layer 122, as shown in FIGS. 12 and 17. As a result, the two third power terminals 15 are electrically connected to the respective third electrodes 221 of the second semiconductor elements 22 via the second conductive layer 122. Each of the two third power terminals 15 outputs the AC power converted by the semiconductor elements 20. In the semiconductor device C, the two third power terminals 15 are spaced apart from each other in the second direction x. Each of the two third power terminals 15 includes a covered portion 151 and an exposed portion 152. As shown in FIG. 17, the covered portion 151 is connected to the second conductive layer 122 and is covered with the sealing resin 50. The covered portion 151 is flush with the second obverse surface 122A of the second conductive layer 122. The exposed portion 152 extends from the covered portion 151 along the first direction z and is exposed externally from the sealing resin 50.

The first wiring 61 is bonded to the first obverse surface 121A of the first conductive layer 121, as shown in FIG. 19. The first wiring 61 is located on the side opposite to the second semiconductor elements 22 with respect to the first semiconductor elements 21 in the first direction z. The first wiring 61 is electrically connected to the first semiconductor elements 21 and the first conductive layer 121. As shown in FIGS. 14 and 19, the first wiring 61 includes a first mounting layer 611, a first metal layer 612, two first gate wiring layers 613, a first detection wiring layer 614, a first temperature detection wiring layer 615 and a second detection wiring layer 616.

The first mounting layer 611 supports the two first gate wiring layers 613, the first detection wiring layer 614, the two first temperature detection wiring layers 615, and the second detection wiring layer 616. The first mounting layer 611 is insulative. The first mounting layer 611 is made of ceramics, for example. Alternatively, the first mounting layer 611 may be made of an insulative resin sheet.

The first metal layer 612 is located on the side facing the first obverse surface 121A of the first conductive layer 121, with respect to the first mounting layer 611 in the third direction y. The first metal layer 612 is bonded to the first mounting layer 611. The first metal layer 612 contains copper. The first metal layer 612 is bonded to the first obverse surface 121A via the second bonding layer 68. The second bonding layer 68 is solder, for example.

The two first gate wiring layers 613 are located on the side opposite to the first metal layer 612 with respect to the first mounting layer 611, as shown in FIGS. 14 and 19. One of the two first gate wiring layers 613 is conductively bonded with a plurality of first wires 4. The first wires 41 are conductively bonded to the respective first gate electrodes 213 of the first semiconductor elements 21, respectively. Furthermore, each of the two first gate wiring layers 613 is conductively bonded with a plurality of seventh wires 47. As a result, the two first gate wiring layers 613 are electrically connected to the respective first gate electrodes 213 of the first semiconductor elements 21.

The first detection wiring layer 614 is located on the side opposite to the first metal layer 612 with respect to the first mounting layer 611, as shown in FIGS. 14 and 19. The first detection wiring layer 614 is bonded to the first mounting layer 611. The first detection wiring layer 614 is conductively bonded with a plurality of second wires 42. Furthermore, the second wires 42 are conductively bonded to the respective first detection electrodes 214 of the first semiconductor elements 21, respectively. As a result, the first detection wiring layer 614 is electrically connected to the first detection electrode 214 of each of the first semiconductor elements 21.

The two first temperature detection wiring layers 615 are located on the side opposite to the first metal layer 612 with respect to the first mounting layer 611, as shown in FIG. 14. The two first temperature detection wiring layers 615 are bonded to the first mounting layer 611. The two first temperature detection wiring layers 615 are adjacent to each other in the second direction x.

The second detection wiring layer 616 is located on the side opposite to the first metal layer 612 with respect to the first mounting layer 611. The second detection wiring layer 616 is bonded to the first mounting layer 611. The second detection wiring layer 616 is conductively bonded to a third wire 43. Furthermore, the third wire 43 is conductively bonded to the first obverse surface 121A of the first conductive layer 121. As a result, the second detection wiring layer 616 is electrically connected to the first conductive layer 121.

The second wiring 62 is conductively bonded to the second obverse surface 122A of the second conductive layer 122, as shown in FIG. 20. The second wiring 62 is located on the side opposite to the first semiconductor elements 21 with respect to the second semiconductor elements 22 in the first direction z. The second wiring 62 is electrically connected to the second semiconductor elements 22 and the second conductive layer 122. As shown in FIGS. 14 and 20, the second wiring 62 has a second mounting layer 621, a second metal layer 622, two second gate wiring layers 623, a third detection wiring layer 624, two second temperature detection wiring layers 625, and a fourth detection wiring layer 626.

The second mounting layer 621 supports the two second gate wiring layers 623, the third detection wiring layer 624, the two second temperature detection wiring layers 625, and the fourth detection wiring layer 626. The second mounting layer 621 is insulative. The second mounting layer 621 is made of ceramics, for example. Alternatively, the second mounting layer 621 may be made of an insulative resin sheet.

The second metal layer 622 is located on the side facing the second obverse surface 122A of the second conductive layer 122, with respect to the second mounting layer 621 in the third direction y. The second metal layer 622 is bonded to the second mounting layer 621. The second metal layer 622 contains copper. The second metal layer 622 is bonded to the second obverse surface 122A via the second bonding layer 68.

The two second gate wiring layers 623 are located on the side opposite to the second metal layer 622 with respect to the second mounting layer 621. One of the two second gate wiring layers 623 is conductively bonded with a plurality of fourth wires 44. The fourth wires 44 are conductively bonded to the respective second gate electrodes 223 of the second semiconductor elements 22. Furthermore, the two second gate wiring layers 623 are conductively bonded to a plurality of eighth wires 48. As a result, the two second gate wiring layers 623 are electrically connected to the respective second gate electrodes 223 of the second semiconductor elements 22.

The third detection wiring layer 624 is located on the side opposite to the second metal layer 622 with respect to the second mounting layer 621, as shown in FIGS. 14 and 20. The third detection wiring layer 624 is bonded to the second mounting layer 621. The third detection wiring layer 624 is conductively bonded with a plurality of fifth wires 45. Furthermore, the fifth wires 45 are conductively bonded to the respective second detection electrodes 224 of the second semiconductor elements 22, respectively. As a result, the third detection wiring layer 624 is electrically connected to the second detection electrodes 224 of each of the second semiconductor elements 22.

The two second temperature detection wiring layers 625 are located on the side opposite to the second metal layer 622 with respect to the second mounting layer 621, as shown in FIG. 14. The two second temperature detection wiring layers 625 are bonded to the second mounting layer 621. The two second temperature detection wiring layers 625 are adjacent to each other in the second direction x.

The fourth detection wiring layer 626 is located on the side opposite to the second metal layer 622 with respect to the second mounting layer 621, as shown in FIG. 14. The fourth detection wiring layer 626 is bonded to the second mounting layer 621.

As shown in FIGS. 19 and 20, each of the sleeves 63 is conductively bonded to the first wiring 61 or the second wiring 62 via the third bonding layer 69. The third bonding layer 69 is solder, for example. The sleeves 63 are made of conductive material such as metal. Each of the sleeves 63 is cylindrical, extending along the third direction y. As shown in FIGS. 11 and 18, each of the sleeves 63 has an end surface 631 facing the same side as the first obverse surface 121A of the first conductive layer 121 in the third direction y. The end surface 631 is exposed externally from a top surface 51 of the sealing resin 50, which will be described later. The third bonding layer 69 is solder, for example.

The thermistor 23 is conductively bonded to the two second temperature detection wiring layers 625 of the second wiring 62, as shown in FIG. 13. The thermistor 23 functions as a sensor for detecting the temperature of the semiconductor device C.

The first signal terminal 161, the second signal terminal 162, the third signal terminal 171, the fourth signal terminal 172, the two fifth signal terminals 18, and the sixth signal terminal 19 are each composed of a metal pin extending along the third direction y. These terminals protrude from the top surface 51 of the sealing resin 50, which will be described later. Furthermore, these terminals are respectively press-fitted into a plurality of sleeves 63. Hence, each of these terminals is supported by one of the sleeves 63 and is electrically connected to one of the first wiring 61 and the second wiring 62.

As shown in FIGS. 14 and 19, the first signal terminal 161 is press-fitted into one of the sleeves 63 that is conductively bonded to one of the two first gate wiring layers 613 of the first wiring 61. Hence, the first signal terminal 161 is electrically connected to the first gate electrode 213 of each of the first semiconductor elements 21 via the two first gate wiring layers 613. The first signal terminal 161 receives a gate voltage to drive the first semiconductor elements 21.

As shown in FIGS. 14 and 20, the second signal terminal 162 is press-fitted into one of the sleeves 63 that is conductively bonded to one of the two second gate wiring layers 623 of the second wiring 62. Hence, the second signal terminal 162 is electrically connected to the second gate electrode 223 of each of the second semiconductor elements 22 via the two second gate wiring layers 623. The second signal terminal 162 receives a gate voltage to drive the second semiconductor elements 22.

As shown in FIG. 11, the third signal terminal 171 is located adjacent to the first signal terminal 161 in the second direction x. As shown in FIG. 14, the third signal terminal 171 is press-fitted into one of the sleeves 63, which is conductively bonded to the first detection wiring layer 614 of the first wiring 61. Hence, the third signal terminal 171 is electrically connected to the first detection electrode 214 of each of the first semiconductor elements 21 via the first detection wiring layer 614. The third signal terminal 171 receives a voltage equivalent to the voltage applied to the first detection electrode 214 of each of the first semiconductor elements 21.

As shown in FIG. 11, the fourth signal terminal 172 is located adjacent to the second signal terminal 162 in the second direction x. As shown in FIG. 14, the fourth signal terminal 172 is press-fitted into one of the sleeves 63, which is conductively bonded to the third detection wiring layer 624 of the second wiring 62. Hence, the fourth signal terminal 172 is electrically connected to the second detection electrode 224 of each of the second semiconductor elements 22 via the third detection wiring layer 624. The fourth signal terminal 172 receives a voltage equivalent to the voltage applied to the second detection electrode 224 of each of the second semiconductor elements 22.

As shown in FIG. 11, the two fifth signal terminals 18 are located on the side opposite to the fourth signal terminal 172 with respect to the second signal terminal 162 in the second direction x. The two fifth signal terminals 18 are adjacent to each other in the second direction x. As shown in FIG. 14, among the sleeves 63, the two fifth signal terminals 18 are respectively press-fitted into the two sleeves 63, which are conductively bonded to the two second temperature detection wiring layers 625 of the second wiring 62, respectively. Hence, the two fifth signal terminals 18 are electrically connected to the thermistor 23 conductively bonded to the two second temperature detection wiring layers 625.

As shown in FIG. 11, the sixth signal terminal 19 is located on the side opposite to the first signal terminal 161 with respect to the third signal terminal 171 in the second direction x. As shown in FIG. 14, the sixth signal terminal 19 is press-fitted into one of the sleeves 63, which is conductively bonded to the second detection wiring layer 616 of the first wiring 61. Hence, the sixth signal terminal 19 is electrically connected to the first conductive layer 121 via the second detection wiring layer 616. The sixth signal terminal 19 receives a voltage corresponding to the DC power input to the first power terminal 13 and the two second power terminals 14.

As shown in FIGS. 14 and 19, the first conductive member 31 is conductively bonded to the second electrodes 212 of the first semiconductor elements 21 and the second obverse surface 122A of the second conductive layer 122. Hence, the second electrode 212 of each of the first semiconductor elements 21 is electrically connected to the second conductive layer 122. The first conductive member 31 contains copper. The first conductive member 31 is a metal clip. As shown in FIG. 14, the first conductive member 31 includes a body portion 311, a plurality of first bonding portions 312, a plurality of first coupling portions 313, a second bonding portion 314, and a second coupling portion 315.

The body portion 311 is a major part of the first conductive member 31. As shown in FIG. 14, the body portion 311 extends along the second direction x. As shown in FIG. 18, the body portion 311 bridges the first conductive layer 121 and the second conductive layer 122.

As shown in FIG. 19, the first bonding portions 312 are conductively bonded to the second electrodes 212 of the first semiconductor elements 21, respectively. Each of the first bonding portions 312 faces the second electrode 212 of one of a corresponding first semiconductor elements 21.

As shown in FIG. 14, the first coupling portions 313 are connected to the body portion 311 and the first bonding portions 312. The first coupling portions 313 are spaced apart from each other in the second direction x. As shown in FIG. 18, as viewed in the second direction x, each of the first coupling portions 313 is inclined away from the first obverse surface 121A of the first conductive layer 121 as it extends from the first bonding portions 312 toward the body portion 311.

As shown in FIGS. 14 and 18, the second bonding portion 314 is conductively bonded to the second obverse surface 122A of the second conductive layer 122. The second bonding portion 314 faces the second obverse surface 122A. The second bonding portion 314 extends along the second direction x. The second bonding portion 314 has a dimension in the second direction x that is equal to a dimension in the second direction x of the body portion 311.

As shown in FIGS. 14 and 18, the second coupling portion 315 is connected to the body portion 311 and the second bonding portion 314. As viewed in the second direction x, the second coupling portion 315 is inclined away from the second obverse surface 122A of the second conductive layer 122 as it extends from the second bonding portion 314 to the body portion 311. The second coupling portion 315 has a dimension in the second direction x that is equal to a dimension in the second direction x of the body portion 311.

As shown in FIGS. 18, 19 and 22, a conductive bonding layer 29 is located between the second electrode 212 of each of the first semiconductor elements 21 and each of the first bonding portions 312. The conductive bonding layer 29 conductively bonds each of the first bonding portions 312 to the second electrode 212 of a corresponding first semiconductor element 21. As shown in FIG. 18, the conductive bonding layer 29 is located between the second obverse surface 122A of the second conductive layer 122 and each second bonding portion 314. The conductive bonding layer 29 conductively bonds the second obverse surface 122A and each second bonding portion 314.

As shown in FIGS. 13 and 20, the second conductive member 32 is conductively bonded to the second electrode 212 of each of the second semiconductor elements 22 and the covered portion 141 of each of the two second power terminals 14. Hence, the second electrode 212 of each of the second semiconductor elements 22 is electrically connected to the two second power terminals 14. The second conductive member 32 contains copper. The second conductive member 32 is a metal clip. As shown in FIG. 13, the second conductive member 32 includes two body portions 321, a plurality of third bonding portions 322, a plurality of third coupling portions 323, two fourth bonding portions 324, two fourth coupling portions 325, a plurality of intermediate portions 326, and a plurality of horizontal beam portions 327.

As shown in FIG. 13, the two body portions 321 are spaced apart from each other in the second direction x. Each of the two body portions 321 extends along the first direction z. As shown in FIG. 17, the two body portions 321 are parallel to the first obverse surface 121A of the first conductive layer 121 and the second obverse surface 122A of the second conductive layer 122. The two body portions 321 are farther from the first obverse surface 121A and the second obverse surface 122A than the body portion 311 of the first conductive member 31.

As shown in FIG. 13, the intermediate portions 326 are spaced apart from each other in the second direction x, and located between the two body portions 321 in the second direction x. Each of the intermediate portions 326 extends along the first direction z. Each of the intermediate portions 326 has a dimension in the first direction z that is smaller than a dimension in the first direction z of each of the two body portions 321.

As shown in FIG. 20, the third bonding portions 322 are conductively bonded to the second electrodes 212 of the second semiconductor elements 22, respectively. Each of the third bonding portions 322 faces the fourth electrode 222 of one of a corresponding second semiconductor elements 22.

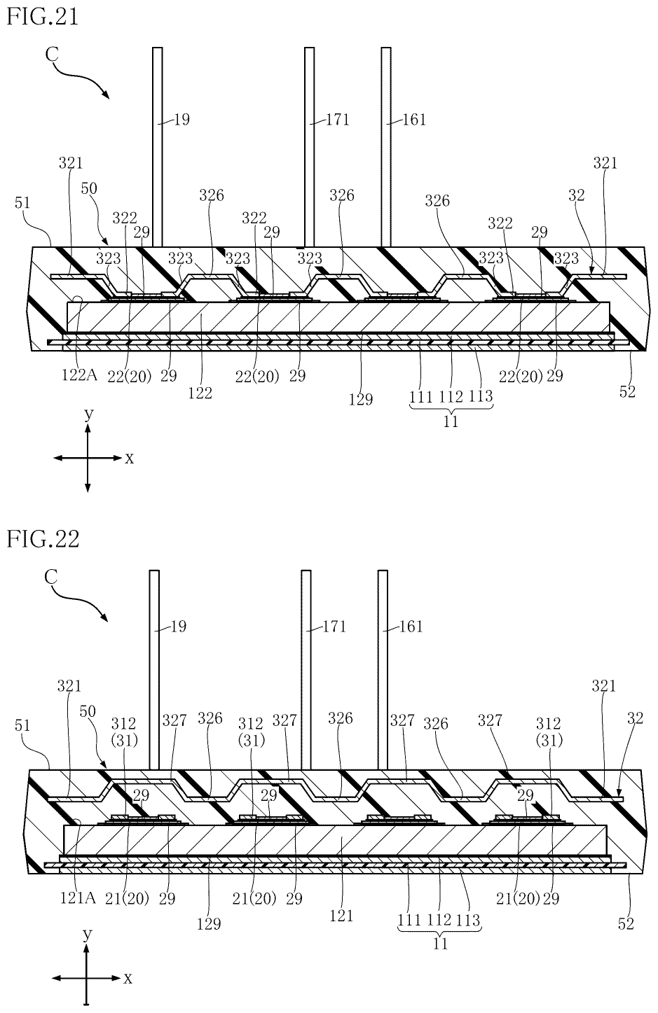

As shown in FIGS. 13 and 21, each of the third coupling portions 323 is connected to either side of the third bonding portions 322 in the second direction x. Further, each of the third coupling portions 323 is connected to any two members selected from the two body portions 321 and the intermediate portions 326. As viewed in the first direction z, each of the third coupling portions 323 is inclined away from the second obverse surface 122A of the second conductive layer 122 as it extends from one of the third bonding portions 322 to one of the two body portions 321 and the intermediate portions 326.

As shown in FIGS. 13 and 17, the two fourth bonding portions 324 are conductively bonded to the respective covered portions 141 of the two second power terminals 14. The two fourth bonding portions 324 face the covered portions 141 of the two second power terminals 14, respectively.

As shown in FIGS. 13 and 17, the two fourth coupling portions 325 are connected to the two body portions 321 and the two fourth bonding portions 324, respectively. As viewed in the second direction x, each of the two fourth coupling portions 325 is inclined away from the first obverse surface 121A of the first conductive layer 121 as it extends from the fourth bonding portion 324 to the body portion 321.

As shown in FIGS. 13 and 22, the horizontal beam portions 327 are arranged along the second direction x. As viewed in the third direction y, the horizontal beam portions 327 include areas overlapping with the respective first bonding portions 312 of the first conductive member 31. Among the horizontal beam portions 327, the two horizontal beam portions 327 located at a central area in the second direction x each have both sides in the second direction x connected to the intermediate portions 326. Among the horizontal beam portions 327, the remaining two horizontal beam portions 327 each have both sides in the second direction x connected to one of the two body portions 321 and one of the intermediate portions 326. As viewed in the first direction z, each of the horizontal beam portions 327 is convex toward the side facing the first obverse surface 121A of the first conductive layer 121 in the third direction y.

As shown in FIGS. 18, 20 and 21, a conductive bonding layer 29 is located between the fourth electrode 222 of each of the second semiconductor elements 22 and each of the third bonding portions 322. The conductive bonding layer 29 conductively bonds each of the third bonding portions 322 to the fourth electrode 222 of a corresponding second semiconductor element 22. As shown in FIG. 17, the conductive bonding layer 29 is located between the covered portion 141 of each of the two second power terminals 14 and each of the two fourth bonding portions 324. The conductive bonding layer 29 conductively bonds the covered portion 141 of each of the two second power terminals 14 to each of the two fourth bonding portions 324.

As shown in FIGS. 17, 18, 21, and 22, the sealing resin 50 covers the first conductive layer 121, the second conductive layer 122, the semiconductor elements 20, the first conductive member 31, and the second conductive member 32. The sealing resin 50 also covers a part of each of the base material 11, the first power terminal 13, the third power terminal 15 and the second power terminal 14. The sealing resin 50 has electrical insulating properties. The sealing resin 50 is made of a material including, for example, a black epoxy resin. As shown in FIGS. 11 and 15 to 18, the sealing resin 50 has a top surface 51, a bottom surface 52, a first side surface 53, a second side surface 54, and two recesses 55.

As shown in FIGS. 17 and 18, the top surface 51 faces the same side as the first obverse surface 121A of the first conductive layer 121 in the third direction y. As shown in FIGS. 17 and 18, the bottom surface 52 faces away from the top surface 51 in the third direction y. As shown in FIG. 16, the heat dissipation layer 113 of the base material 11 is exposed from the bottom surface 52.

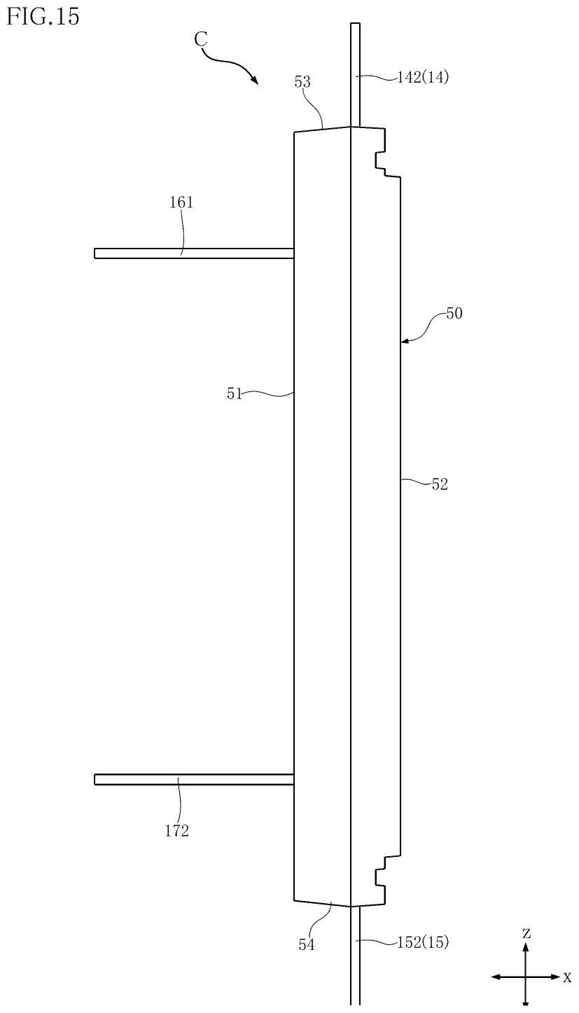

As shown in FIGS. 11 and 15, the first side surface 53 and the second side surface 54 are spaced apart from each other in the first direction z. The first side surface 53 and the second side surface 54 face away from each other in the first direction z. From the first side surface 53, the exposed portion 132 of the first power terminal 13 and the exposed portions 142 of the two second power terminals 14 are externally exposed. From the second side surface 54, the exposed portions 152 of the two third power terminals 15 are externally exposed.

As shown in FIGS. 11 and 16, each of the two recesses 55 extends from the first side surface 53 toward the first direction z. Each of the two recesses 55 reaches from the top surface 51 to the bottom surface 52 in the third direction y. The two recesses 55 are located on both sides of the first power terminal 13 in the second direction x, respectively.

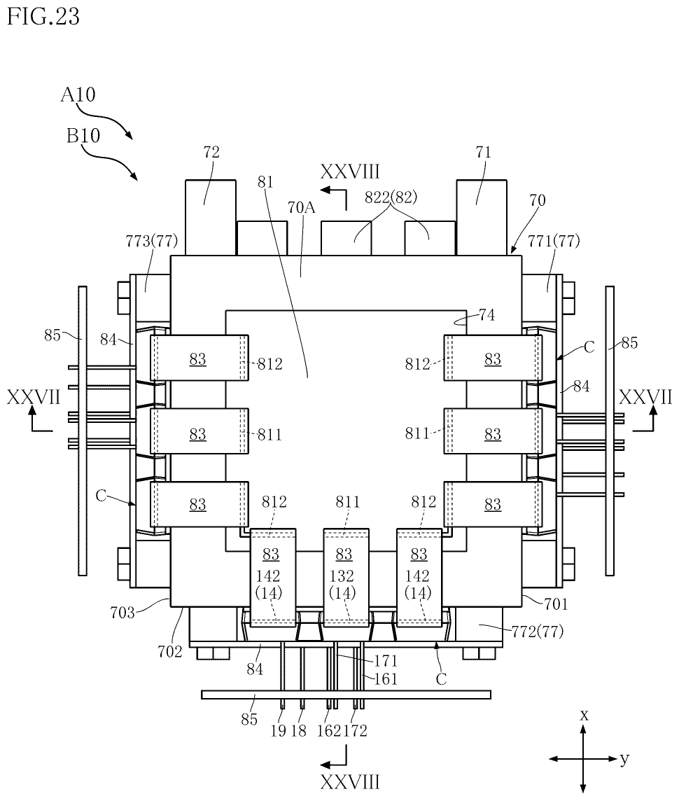

Next, the configuration of the semiconductor module A10 will be explained based on FIGS. 23 to 29.

The semiconductor devices C are respectively mounted on the first surface 701, the second surface 702 and the third surface 703 of the housing 70. In the semiconductor module A10, the first power terminal 13 and the two second power terminals 14 of each semiconductor device C are disposed closer to the obverse surface 70A than the reverse surface 70B of the housing 70.

The attachment members 84 allows the respective semiconductor devices C to be attached to the housing 70 via a corresponding attachment portion 77. The attachment members 84 may be flat plates, for example. Alternatively, the attachment portions 84 may be plate springs. Each of the attachment members 84 is fastened to a corresponding heat dissipation body 76 with bolts or the like.

The capacitor 81 is electrically connected to each of the semiconductor devices C. As shown in FIGS. 23, 25, and 27 to 29, at least a part of the capacitor 81 is housed in the receiving portion 74 of the housing 70. The capacitor 81 receives DC power from an external source, which is to be converted by the semiconductor module A10. The capacitor 81 has a plurality of first terminals 811 and a plurality of second terminals 812. Each of the first terminals 811 and the second terminals 812 protrudes in the side that the obverse surface 70A of the housing 70 faces in the first direction z. In the semiconductor module A10, the first terminals 811 and the second terminals 812 are located outside the receiving portion 74. Each of the first terminals 811 is electrically connected to the first power terminal 13 of a corresponding semiconductor device C. Each of the second terminals 812 is electrically connected to the two second power terminals 14 of a corresponding semiconductor device C.

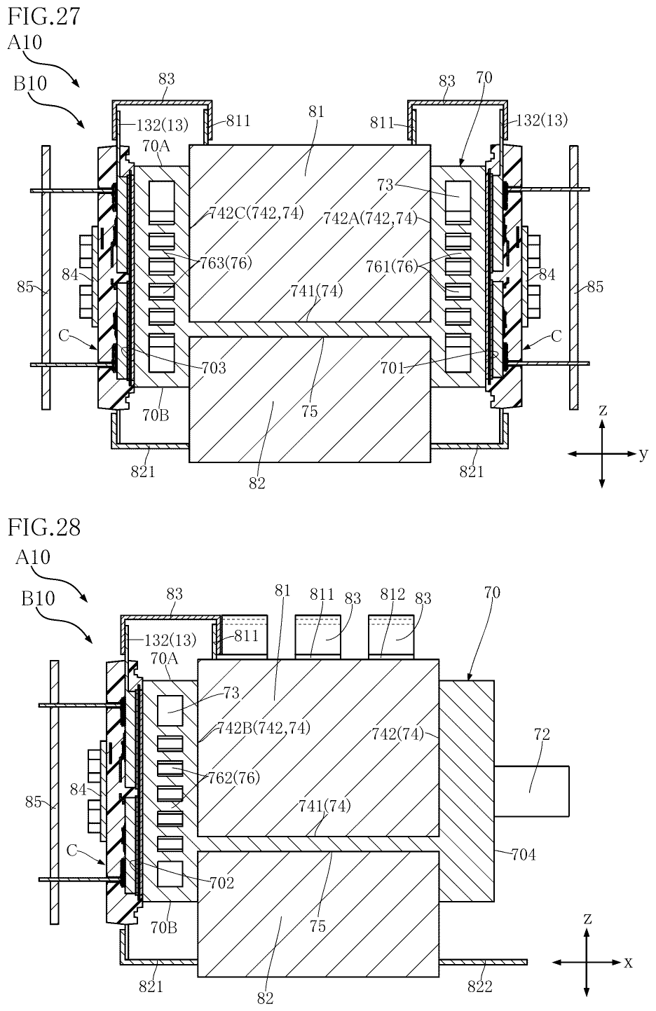

As shown in FIGS. 27 to 29, the capacitor 81 is in contact with the intermediate surface 741 and the inner circumferential surface 742 of the housing 70, which define the receiving portion 74. Further, the capacitor 81 is in contact with the first area 742A, the second area 742B, and the third area 742C of the inner circumferential surface 742.

As shown in FIGS. 23 to 25, 27 and 28, each of the busbars 83 is conductively bonded to either the exposed portion 132 of the first power terminal 13 or to one of the exposed portions 142 of the two second power terminals 14 in each of the semiconductor devices C. Each of the busbars 83 is also conductively bonded to either one of the first terminals 811 or one of the second terminals 812 of the capacitor 81. Hence, the capacitor 81 is electrically connected to the first power terminal 13 and the two second power terminals 14 of the semiconductor devices C. Each of the busbars 83 is formed from a piece of metal containing copper, for example. Each of the busbars 83 is bent around either the second direction x or the third direction y.

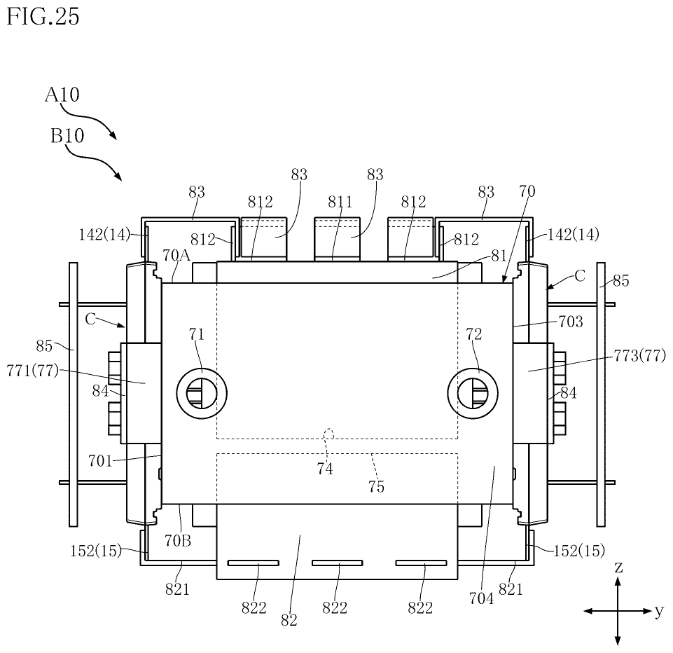

The current sensor 82 is electrically connected to the semiconductor devices C. As shown in FIGS. 25 to 28, the current sensor 82 is mounted in the recess 75 of the housing 70. Hence, the current sensor 82 is located on one side of the first direction z of the receiving portion 74 of the housing 70. A part of the current sensor 82 is housed in the recess 75. The current sensor 82 has a plurality of third terminals 821 and a plurality of fourth terminals 822. Each of the third terminals 821 is conductively bonded to the exposed portions 152 of the two third power terminals 15 of each semiconductor device C. Each of the fourth terminals 822 extends along the second direction x toward the side on which the fourth surface 704 of the housing 70 is located relative to the recess 75. The fourth terminals 822 output three-phase (U-phase, V-phase, and W-phase) AC power.

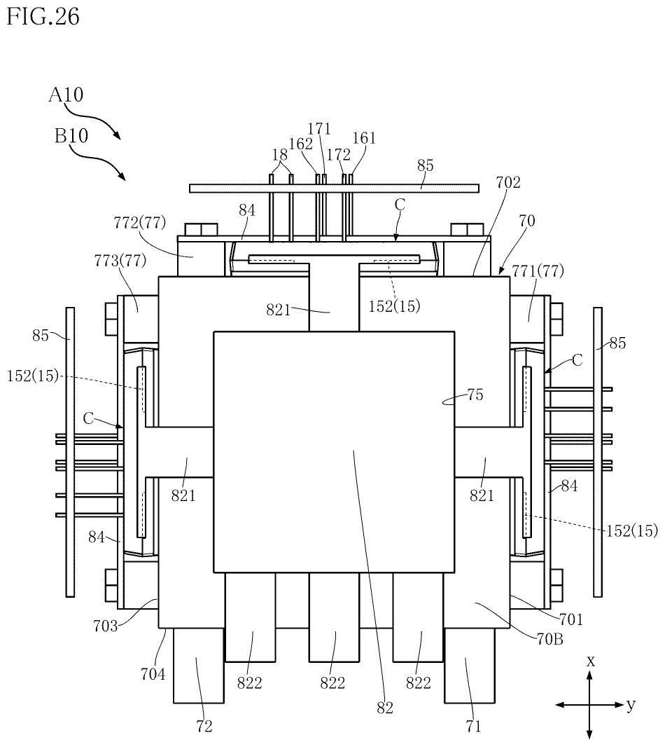

As shown in FIGS. 23 and 26, each of the wiring boards 85 is attached to the first signal terminal 161, the second signal terminal 162, the third signal terminal 171, the fourth signal terminal 172, the two fifth signal terminals 18, and the sixth signal terminal 19 of each semiconductor device C. Each of these terminals is inserted into one of the wiring boards 85 in a direction orthogonal to the first direction z.

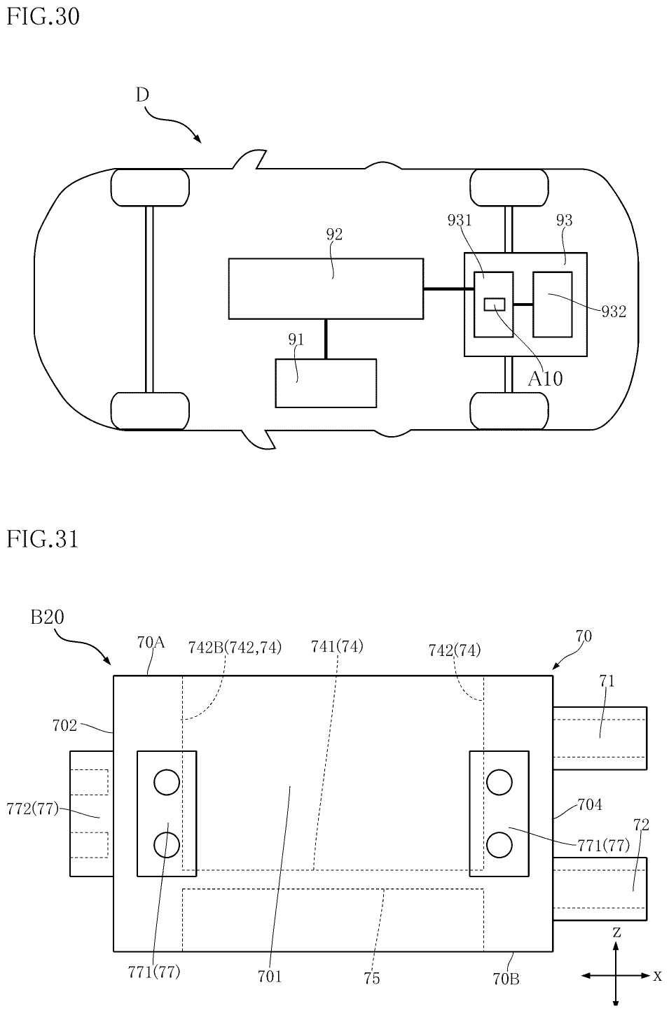

Next, a vehicle D in which the semiconductor module A10 is mounted will be described based on FIG. 30. The vehicle D is, for example, an electric vehicle (EV).

As shown in FIG. 30, the vehicle D comprises an on-board battery charger 91, a storage battery 92, and a driving system 93. The on-board battery charger 91 wirelessly receives electric power from a power supply facility (not shown) installed outdoors. Alternatively, the power supply from the power supply facility to the on-board battery charger 91 may be provided via a wired connection. The on-board battery charger 91 comprises a boost type DC-DC converter. The voltage of the power supplied to the on-board battery charger 91 is boosted by the converter and then fed to the storage battery 92. The boosted voltage is, for example, 600 V.

The driving system 93 drives the vehicle D. The driving system 93 includes an inverter 931 and a drive source 932. The semiconductor module A10 constitutes part of the inverter 931. Electric power stored in the storage battery 92 is supplied to the inverter 931. The electric power supplied from the storage battery 92 to the inverter 931 is DC power. Alternatively, in an example different from that shown in FIG. 30, a boost type DC-DC converter may be further provided between the storage battery 92 and the inverter 931. The inverter 931 converts DC power to AC power. The inverter 931, which includes semiconductor module A10, is electrically connected to the drive source 932. The drive source 932 includes an AC motor and a transmission. When the AC power converted by the inverter 931 is supplied to the drive source 932, the AC motor rotates and its rotation is transmitted to the transmission. The transmission rotates the drive shaft of the vehicle D after reducing the number of revolutions transmitted from the AC motor as appropriate. This drives the vehicle D. In driving the vehicle D, it is necessary to freely control the rotation speed of the AC motor based on information such as the amount of variation of the accelerator pedal. In order to address this, the semiconductor module A10 in the inverter 931 is necessary to output AC power whose frequency varies in accordance with the required rotation speed of the AC motor.

Next, operative effects of the semiconductor module A10 are as follows. The semiconductor module A10 comprises the cooler B10, the semiconductor devices C, and the capacitor 81. The cooler B10 includes the housing 70 having the first surface 701, the second surface 702, the third surface 703, the hollow portion 73, and the receiving portion 74. At least a part of the capacitor 81 is housed in the receiving portion 74. Each of the first surface 701, the second surface 702, and the third surface 703 faces away from the receiving portion 74 with respect to the hollow portion 73 in a direction orthogonal to the first direction z. The first surface 701, the second surface 702 and the third surface 703 each have a different normal direction N (see FIG. 3). With this configuration, the semiconductor devices C are mounted on the housing 70 so as to be disposed externally around the capacitor 81 as viewed in the first direction z. This allows reduction in the dimensions of the semiconductor module A10 in the directions orthogonal to the first direction z, thereby making it possible to reduce the overall size of the semiconductor module A10.

In the housing 70, the second surface 702 is located between the first surface 701 and the third surface 703. The first surface 701 and the second surface 702 are adjacent to each other. The first surface 701 and the second surface 702 form an internal angle α (see FIG. 3) that is equal to or greater than 90 degrees as viewed in the first direction. This may reduce the loss of refrigerant flowing through the hollow portion 73 due to the bending of the hollow portion 73.

The housing 70 has the inner circumferential surface 742 defining the receiving portion 74. The capacitor 81 is in contact with the inner circumferential surface 742. With this configuration, heat generated from the capacitor 81 is transferred through the inner circumferential surface 742 to the refrigerant flowing through the hollow portion 73. This may cool the capacitor 81 in addition to the semiconductor devices C in the semiconductor module A10.

The inner circumferential surface 742 defining the receiving portion 74 includes the first area 742A facing away from the first surface 701, and the second area 742B facing away from the second surface 702. The capacitor 81 is in contact with the first area 742A and the second area 742B. This configuration increases the contact area between the capacitor 81 and the inner circumferential surface 742, thereby improving the cooling efficiency of the capacitor 81.

The cooler B10 further comprises the heat dissipation body 76 housed in the hollow portion 73. As viewed in a direction orthogonal to the first direction z, the heat dissipation bodies 76 respectively overlap with the first surface 701, the second surface 702 and the third surface 703. This configuration may improve the cooling efficiency at each of the first surface 701, the second surface 702 and the third surface 703.

Each of the heat dissipation bodies 76 is connected to each of the first peripheral surface 731 and the second peripheral surface 732 defining the hollow portion 73. This configuration may improve both the cooling efficiency at each of the first surface 701, the second surface 702 and the third surface 703, as well as the cooling efficiency at the inner circumferential surface 742 defining the receiving portion 74.

The semiconductor module A10 further comprises the current sensor 82 mounted on the housing 70. The current sensor 82 is located on one side in the first direction z with respect to the receiving portion 74. This configuration may reduce an increase in the size of the semiconductor module A10 in a direction orthogonal to the first direction z, even when the semiconductor module A10 includes the current sensor 82.

### Second Embodiment

A semiconductor module A20 according to a second embodiment of the present disclosure will be described based on FIGS. 31 to 33. In these figures, elements identical or similar to those of the semiconductor module A10 described above are marked with the same symbols, and redundant descriptions are omitted.

The semiconductor module A20 comprises a cooler B20 instead of the cooler B10. The cooler B20 differs from the cooler B10 in the configuration of the housing 70.

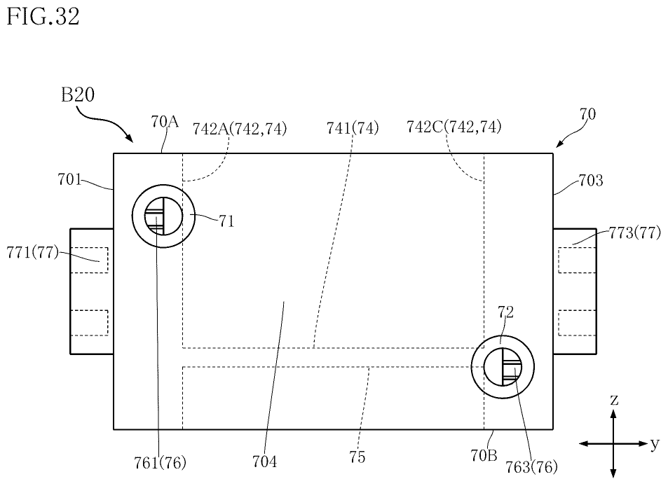

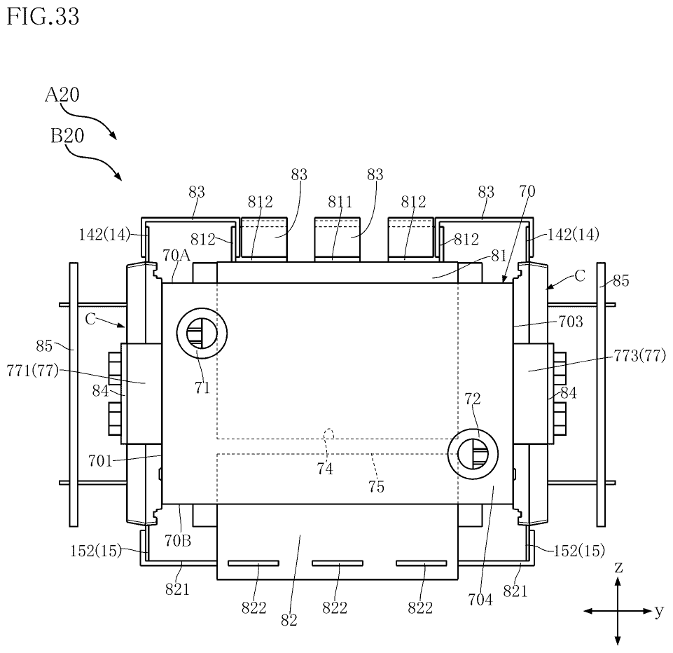

As shown in FIGS. 31 and 32, in the first direction z, the inlet 71 has a center located closer to the obverse surface 70A of the housing 70 than a center of the outlet 72. FIG. 33 shows the cooler B20 in the configuration of the semiconductor module A20.

Next, operative effects of the semiconductor module A20 are as follows.

The semiconductor module A20 comprises the cooler B20, the semiconductor devices C, and the capacitor 81. The cooler B20 includes the housing 70 having the first surface 701, the second surface 702, the third surface 703, the hollow portion 73, and the receiving portion 74. At least a part of the capacitor 81 is housed in the receiving portion 74. Each of the first surface 701, the second surface 702, and the third surface 703 faces away from the receiving portion 74 with respect to the hollow portion 73 in a direction orthogonal to the first direction z. Each of the first surface 701, the second surface 702 and the third surface 703 has a different normal direction N (see FIG. 3). Therefore, this configuration also allows for a reduction in the overall size of the semiconductor module A20. In addition, the semiconductor module A20 may have a configuration in common with the semiconductor module A10, thereby achieving the same effect as the semiconductor module A10.

The cooler B20 in the semiconductor module A20 includes the inlet 71 having a center located closer to the obverse surface 70A of the housing 70 than a center of the outlet 72 in the first direction z. When the first direction z of the semiconductor module A20 is oriented vertically, this configuration allows the refrigerant flowing through the hollow portion 73 to exhibit a more uniform temperature distribution along the first direction z. This may improve the cooling efficiency of the semiconductor module A20.

### Third Embodiment

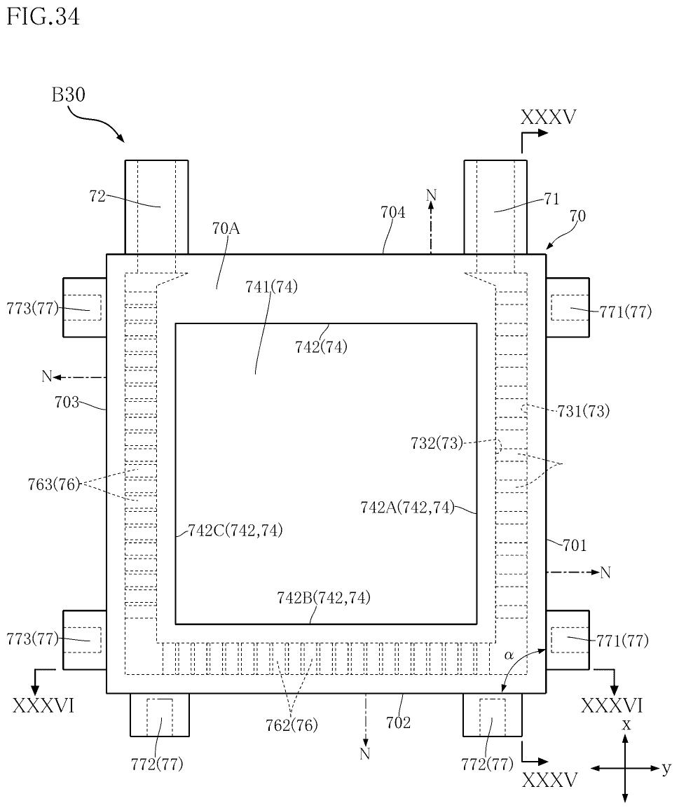

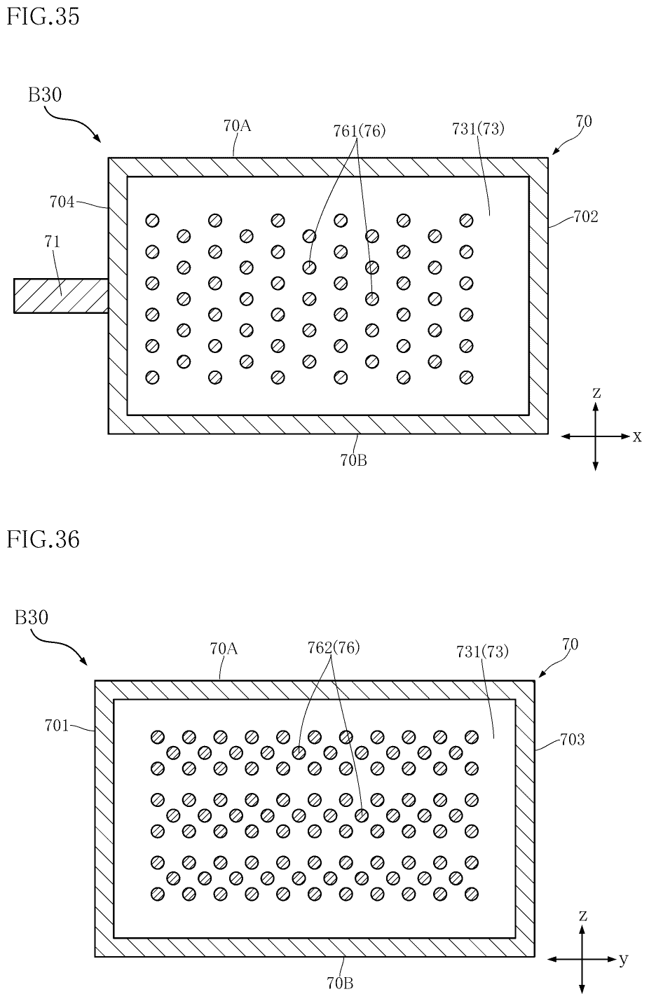

A semiconductor module A30 according to a third embodiment of the present disclosure will be described based on FIGS. 34 to 37. In these figures, elements identical or similar to those of the aforementioned semiconductor module A10 are marked with the same symbols, and redundant explanations are omitted.

The semiconductor module A30 comprises a cooler B30 instead of the cooler B10. The cooler B30 differs from the cooler B10 in the configuration of the heat dissipation bodies 76.

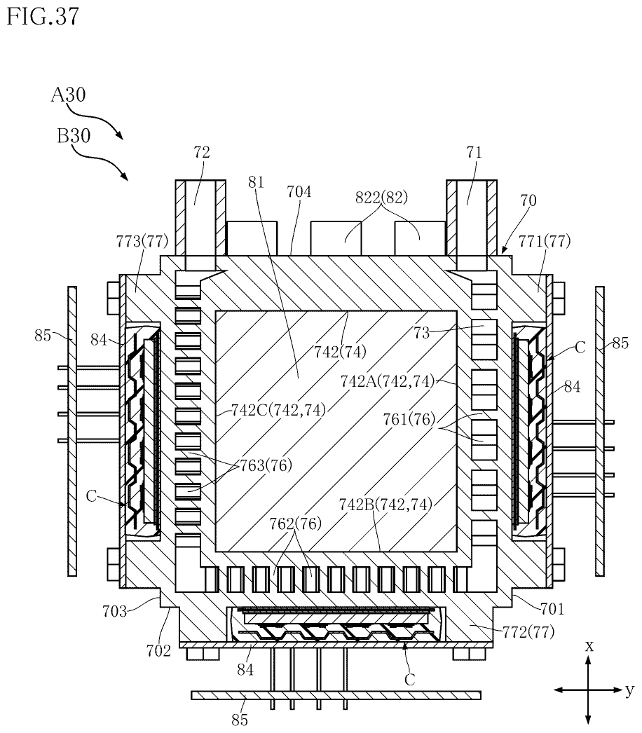

As shown in FIGS. 34 to 36, among the heat dissipation bodies 76, the second heat dissipation body 762 has a surface area greater than a surface area of the first heat dissipation body 761. Further, among the heat dissipation bodies 76, the third heat dissipation body 763 has a surface area equal to a surface area of the first heat dissipation body 761 of the cooler B10 shown in FIG. 8. Therefore, the surface area of the third heat dissipation body 763 is greater than that of the second heat dissipation body 762. In other words, in the heat dissipation bodies 76, the first heat dissipation body 761, the second heat dissipation body 762, and the third heat dissipation body 763 are configured such that their surface areas increase in this order. FIG. 37 shows the cooler B30 in the configuration of the semiconductor module A30.

As in the previously described cooler B20, the cooler B30 of the semiconductor module A30 may also be configured such that the inlet 71 has a center closer to the obverse surface 70A of the housing 70 than a center of the outlet 72 in the first direction z.

Next, operative effects of the semiconductor module A30 are as follows. The semiconductor module A30 comprises the cooler B30, the semiconductor devices C, and the capacitor 81. The cooler B30 includes the housing 70 having the first surface 701, the second surface 702, the third surface 703, the hollow portion 73, and the receiving portion 74. At least a part of the capacitor 81 is housed in the receiving portion 74. Each of the first surface 701, the second surface 702, and the third surface 703 faces away from the receiving portion 74 with respect to the hollow portion 73 in a direction orthogonal to the first direction z. Each of the first surface 701, the second surface 702 and the third surface 703 has a different normal direction N (see FIG. 3). Therefore, this configuration also allows for a reduction in the overall size of the semiconductor module A30. In addition, the semiconductor module A30 may have a configuration in common with the semiconductor module A10, thereby achieving the same effect as the semiconductor module A10.

In the cooler B30 included in the semiconductor module A30, among the heat dissipation bodies 76, the second heat dissipation body 762 has a surface area greater than a surface area of the first heat dissipation body 761. With this configuration, the contact area between the first heat dissipation body 761 and the refrigerant with relatively low temperature is smaller than the contact area between the second heat dissipation body 762 and the refrigerant with higher temperature than the refrigerant contacting the first heat dissipation body 761. This reduces the difference in the amount of heat transferred to the refrigerant between the first heat dissipation body 761 and the second heat dissipation body 762. Hence, it is possible to achieve uniform cooling efficiency on each of the first surface 701 and the second surface 702 of the housing 70.

As in the previously described cooler B20, the cooler B30 of the semiconductor module A30 may also be configured such that the inlet 71 has a center closer to the obverse surface 70A of the housing 70 than a center of the outlet 72 in the first direction z (see FIG. 33). With this configuration, the semiconductor module A30 achieves the same effect as the semiconductor module A20.

### Fourth Embodiment

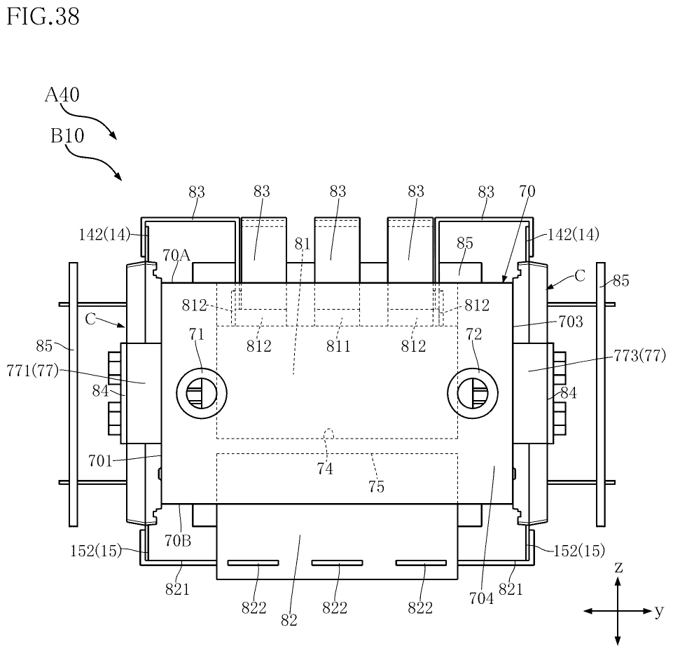

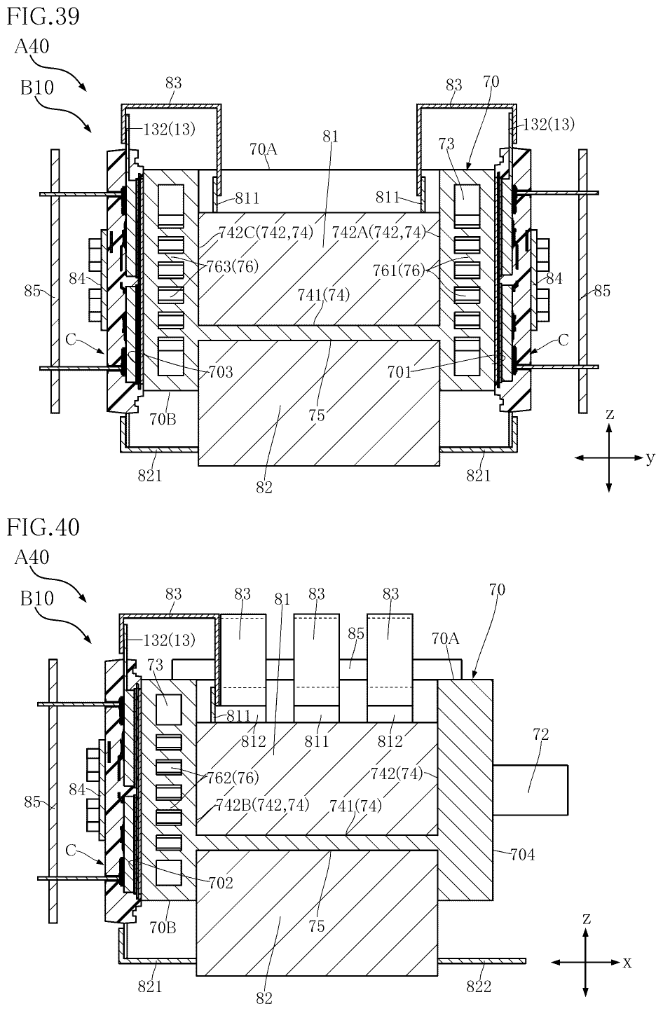

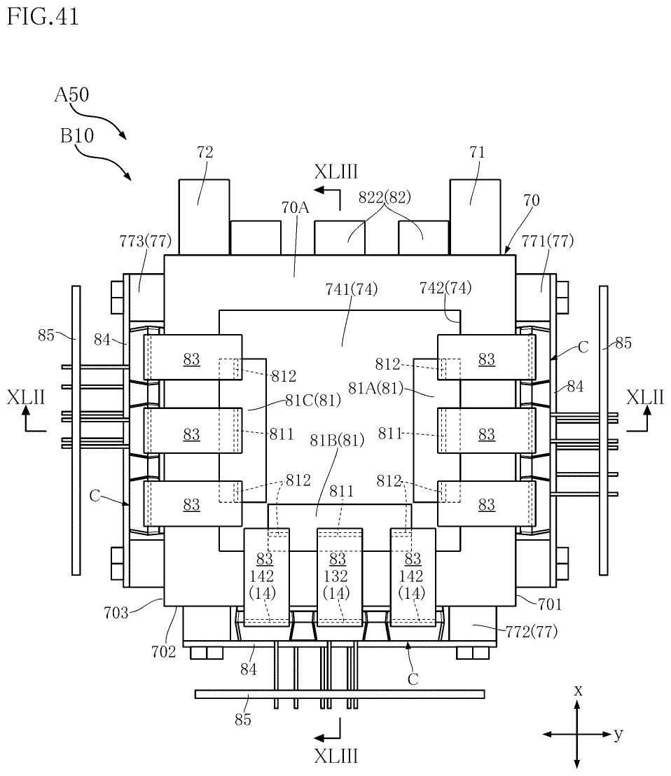

A semiconductor module A40 according to a fourth embodiment of the present disclosure will be described based on FIGS. 38 to 40. In these figures, elements identical or similar to those of the aforementioned semiconductor module A10 are marked with the same symbols, and redundant explanations are omitted.

The semiconductor module A40 differs from the semiconductor module A10 in the configuration of the capacitor 81.

As shown in FIGS. 38 to 40, the entire capacitor 81, including the first terminals 811 and the second terminals 812, is housed in the receiving portion 74 of the housing 70. The capacitor 81 is in contact with the inner circumferential surface 742 of the housing 70 defining the receiving portion 74. As viewed in a direction orthogonal to the first direction z, the first terminals 811 and the second terminals 812 overlap with the receiving portion 74.

Next, operative effects of the semiconductor module A40 are as follows. The semiconductor module A40 comprises the cooler B10, the semiconductor devices C, and the capacitor 81. The cooler B10 includes the housing 70 having the first surface 701, the second surface 702, the third surface 703, the hollow portion 73, and the receiving portion 74. At least a part of the capacitor 81 is housed in the receiving portion 74. Each of the first surface 701, the second surface 702, and the third surface 703 faces away from the receiving portion 74 with respect to the hollow portion 73 in a direction orthogonal to the first direction z. The first surface 701, the second surface 702 and the third surface 703 each have a different normal direction N (see FIG. 3). Therefore, this configuration also allows for a reduction in the overall size of the semiconductor module A40. In addition, the semiconductor module A40 may have a configuration in common with the semiconductor module A10, thereby achieving the same effect as the semiconductor module A10.

In the semiconductor module A40, the entire capacitor 81 is housed in the receiving portion 74 of the housing 70. This configuration may increase the contact area of the capacitor 81 with the inner circumferential surface 742 of the housing 70 defining the receiving portion 74. This may improve the cooling efficiency of the capacitor 81.

### Fifth Embodiment

A semiconductor module A50 according to a fifth embodiment of the present disclosure will be described based on FIGS. 41 to 43. In these figures, elements that are identical or similar to the aforementioned semiconductor module A10 are marked with the same symbol, and redundant explanations are omitted.

The semiconductor module A50 differs from the semiconductor module A10 in the configuration of the capacitor 81.

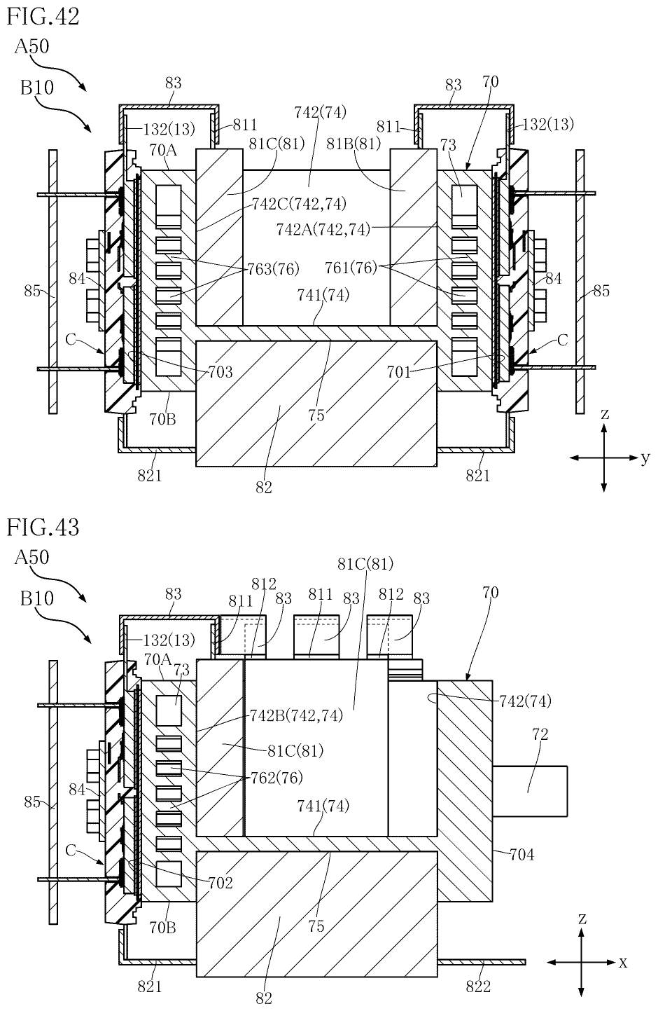

As shown in FIG. 41, the capacitor 81 includes a first capacitor 81A, a second capacitor 81B and a third capacitor 81C, which are separated from each other. Each of the first capacitor 81A, the second capacitor 81B, and the third capacitor 81C has a first terminal 811 and two second terminals 812. As shown in FIG. 42, the first capacitor 81A is in contact with the first area 742A of the inner circumferential surface 742 defining the receiving portion 74 of the housing 70. As shown in FIG. 43, the second capacitor 81B is in contact with the second area 742B of the inner circumferential surface 742. As shown in FIG. 42, the third capacitor 81C is in contact with the third area 742C of the inner circumferential surface 742.

Next, operative effects of the semiconductor module A50 are as follows. The semiconductor module A50 comprises the cooler B10, the semiconductor devices C, and the capacitor 81. The cooler B10 includes the housing 70 having the first surface 701, the second surface 702, the third surface 703, the hollow portion 73, and the receiving portion 74. At least a part of the capacitor 81 is housed in the receiving portion 74. Each of the first surface 701, the second surface 702, and the third surface 703 faces away from the receiving portion 74 with respect to the hollow portion 73 in a direction orthogonal to the first direction z. The first surface 701, the second surface 702 and the third surface 703 each have a different normal direction N (see FIG. 3). Therefore, this configuration also allows for a reduction in the overall size of the semiconductor module A50. In addition, the semiconductor module A50 may have a configuration in common with the semiconductor module A10, thereby achieving the same effect as the semiconductor module A10.

In the semiconductor module A50, the capacitor 81 includes the first capacitor 81A and the second capacitor 81B that are separated from each other. The first capacitor 81A is in contact with the first area 742A of the inner circumferential surface 742 defining the receiving portion 74 of the housing 70. The second capacitor 81B is in contact with the second area 742B of the receiving portion 74. This configuration may reduce uneven heat distribution in the capacitor 81. Thus, the cooling efficiency of the capacitor 81 may be improved.

### Sixth Embodiment

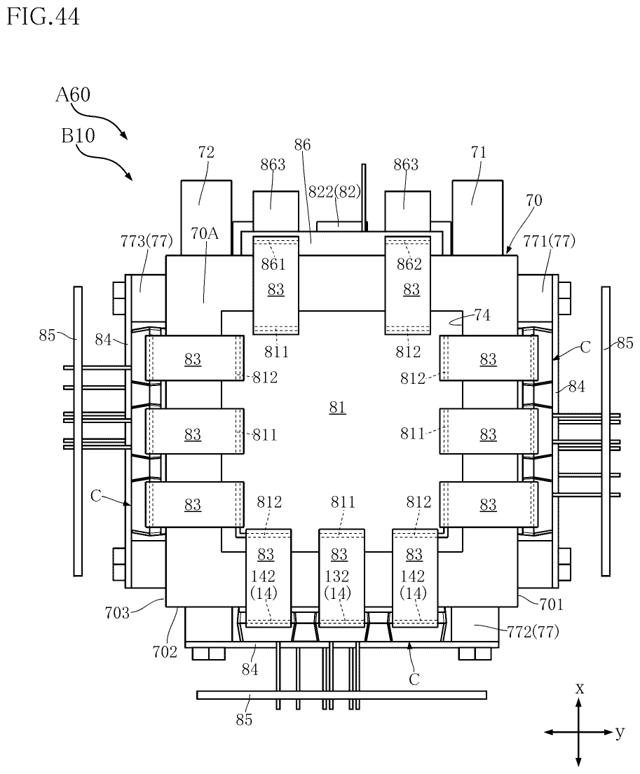

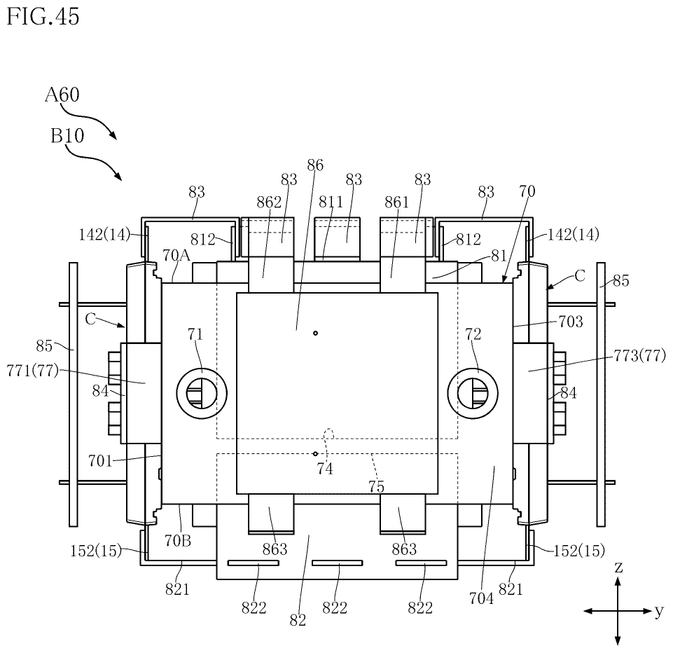

A semiconductor module A60 according to a sixth embodiment of the present disclosure will be described based on FIGS. 44 and 45. In these figures, elements identical or similar to those of the aforementioned semiconductor module A10 are marked with the same symbols, and redundant descriptions are omitted.

The semiconductor module A60 differs from the semiconductor module A10 in that it further comprises an exciter 86.

The exciter 86 is mounted on the fourth surface 704 of the housing 70. The exciter 86 includes a plurality of switching elements such as IGBTs, and a plurality of diodes. The exciter 86 has a fifth terminal 861, a sixth terminal 862, and two seventh terminals 863. The fifth terminal 861 is electrically connected to one of the first terminals 811 of the capacitor 81 via the busbar 83. The sixth terminal 862 is electrically connected to one of the second terminals 812 of the capacitor 81 via the busbar 83. The two seventh terminals 863 are located on the side opposite to the fifth terminal 861 and the sixth terminal 862 in the first direction z. Power input to the fifth terminal 861 and the sixth terminal 862 is converted by the switching elements and diodes and then output from the two seventh terminals 863.

Next, operative effects of the semiconductor module A60 are as follows.

The semiconductor module A60 comprises the cooler B10, the semiconductor devices C, and the capacitor 81. The cooler B10 includes the housing 70 having the first surface 701, the second surface 702, the third surface 703, the hollow portion 73, and the receiving portion 74. At least a part of the capacitor 81 is housed in the receiving portion 74. Each of the first surface 701, the second surface 702, and the third surface 703 faces away from the receiving portion 74 with respect to the hollow portion 73 in a direction orthogonal to the first direction z. The first surface 701, the second surface 702 and the third surface 703 each have a different normal direction N (see FIG. 3). Therefore, this configuration also allows for a reduction in the overall size of the semiconductor module A60. In addition, the semiconductor module A60 may have a configuration in common with the semiconductor module A10, thereby achieving the same effect as the semiconductor module A10.

The semiconductor module A60 further comprises the exciter 86 mounted on the housing 70. The exciter 86 is electrically connected to the capacitor 81. This configuration allows the semiconductor module A60 to be applied as an inverter for a motor that does not require a permanent magnet. Specifically, the fourth terminals 822 of the current sensor 82 are connected to a stator of the motor. The two seventh terminals 863 of the exciter 86 are connected to a rotor of the motor. This may allow a magnetic field to be generated in the rotor in a controlled manner, without requiring a permanent magnet.

The present disclosure is not limited to the embodiments described above. The specific configurations of each component of the present disclosure may be modified in various ways. In the semiconductor module of the present disclosure, three semiconductor devices C are mounted on a single cooler. However, the number of the semiconductor devices C is not limited thereto. In the housing 70 of the cooler, the number of surfaces for mounting the semiconductor devices C is not limited to the first surface 701, the second surface 702, and the third surface 703, and may be set as desired. For example, the housing 70 may have a hexagonal or octagonal shape as viewed in the first direction z. In such a case, four or more semiconductor devices C can be mounted in the housing 70.

The present disclosure includes the embodiments described in the following clauses.

### Clause 1.

A semiconductor module comprising:
a cooler;
a plurality of semiconductor devices mounted on the cooler; and
a capacitor electrically connected to each of the plurality of semiconductor devices and housed in the cooler,
wherein the cooler includes a housing having a receiving portion and a hollow portion that is located around and outwardly surrounds the receiving portion as viewed in a first direction,
the housing has a first surface, a second surface, and a third surface on which the plurality of semiconductor devices are respectively mounted,
each of the first surface, the second surface, and the third surface faces away from the receiving portion with respect to the hollow portion in a direction orthogonal to the first direction,
the first surface, the second surface and the third surface each have a different normal direction, and
at least a part of the capacitor is housed in the receiving portion.

### Clause 2.

The semiconductor module according to clause 1, wherein the housing has an obverse surface facing one side in the first direction, and
the receiving portion has an opening on the obverse surface.

### Clause 3.

The semiconductor module according to clause 2, wherein the second surface is located between the first surface and the third surface,
the first surface and the second surface are adjacent to each other, and
the first surface and the second surface form an internal angle that is equal to or greater than 90 degrees as viewed in the first direction.

### Clause 4.

The semiconductor module according to clause 3, wherein the first surface and the third surface face away from each other in a direction orthogonal to the first direction.

### Clause 5.

The semiconductor module according to clause 3, wherein the housing has an inner circumferential surface that faces a direction orthogonal to the first direction and defines the receiving portion, and
the capacitor is in contact with the inner circumferential surface.

### Clause 6.

The semiconductor module according to clause 5, wherein the inner circumferential surface includes a first area facing away from the first surface in a direction orthogonal to the first direction and a second area facing away from the second surface in a direction orthogonal to the first direction, and
the capacitor is in contact with each of the first area and the second area.

### Clause 7.

The semiconductor module according to clause 6, wherein the capacitor includes a first capacitor and a second capacitor separated from each other,
the first capacitor is in contact with the first area, and
the second capacitor is in contact with the second area.

### Clause 8.

The semiconductor module according to any one of clauses 5 to 7, wherein the entire capacitor is housed in the receiving portion.

### Clause 9.

The semiconductor module according to clause 5, wherein the housing has an inlet and an outlet, each communicating with the hollow portion, and
the inlet is located closer to the first surface than the outlet.

### Clause 10.

The semiconductor module according to clause 9, wherein the housing has a fourth surface facing a direction orthogonal to the first direction,
the fourth surface is located an opposite side of the second surface with respect to the first surface, and
the inlet and the outlet are provided on the fourth surface.

### Clause 11.

The semiconductor module according to clause 10, wherein the inlet has a center located closer to the obverse surface than a center of the outlet in the first direction.

### Clause 12.

The semiconductor module according to clause 10, wherein the cooler further includes a plurality of heat dissipation bodies housed in the hollow portion, and
the plurality of heat dissipation bodies respectively overlap with the first surface, the second surface, and the third surface as viewed in a direction orthogonal to the first direction.

### Clause 13.

The semiconductor module according to clause 12, wherein the housing has a first peripheral surface and a second peripheral surface that face each other in a direction orthogonal to the first direction and define the hollow portion,
the second peripheral surface is located between the first peripheral surface and the inner circumferential surface, and
each of the plurality of heat dissipation bodies is connected to the first peripheral surface.

### Clause 14.

The semiconductor module according to clause 13, wherein each of the plurality of heat dissipation bodies is connected to the second peripheral surface.

### Clause 15.

The semiconductor module according to clause 14, wherein the plurality of heat dissipation bodies includes a first heat dissipation body and a second heat dissipation body,
the first heat dissipation body is connected to an area of the first peripheral surface facing away from the first surface in a direction orthogonal to the first direction,
the second heat dissipation body is connected to an area of the second peripheral surface facing away from the second surface in a direction orthogonal to the first direction,
the second heat dissipation body has a surface area greater than a surface area of the first heat dissipation body.

### Clause 16.

The semiconductor module according to any one of clauses 10 to 15, further comprising a current sensor mounted on the housing,
wherein the current sensor is electrically connected to each of the plurality of semiconductor devices, and
the current sensor is located on one side in the first direction with respect to the receiving portion.

### Clause 17.

The semiconductor module according to clause 12, further comprising an exciter mounted on the housing,
wherein the exciter is electrically connected to the capacitor.

### Clause 18.

A vehicle comprising:
a drive source; and
the semiconductor module according to clause 12,
wherein the semiconductor module is electrically connected to the drive source.

### REFERENCE NUMERALS

REFERENCE NUMERALS

| | | |
|---|---|---|
| A10 to A60: Semiconductor module | B10 to B30: Cooler | |
| C: Semiconductor device | D: Vehicle | |
| 11: Base material | 111: Insulative layer | |
| 111A: Peripheral edge | 112: Intermediate layer | |
| 113: Heat dissipation layer | 121: First conductive layer | |
| 121A: First obverse surface | 122: Second support layer | |
| 122A: Second obverse surface | 129: First bonding layer | |
| 13: First power terminal | 131: Covered portion | |
| 132: Exposed portion | 14: Second power terminal | |
| 141: Covered portion | 142: Exposed portion | |
| 15: Third power terminal | 151: Covered portion | |
| 152: Exposed portion | 161: First signal terminal | |
| 162: Second signal terminal | 171: Third signal terminal | |
| 172: Fourth signal terminal | 18: Fifth signal terminal | |
| 19: Sixth signal terminal | 20: Semiconductor element | |
| 21: First semiconductor element | 211: First electrode | |
| 212: Second electrode | 213: First gate electrode | |
| 214: First detection electrode | 22: Second semiconductor element | |
| 221: Third electrode | 222: Fourth electrode | |
| 223: Second gate electrode | 224: Second detection electrode | |
| 23: Thermistor | 29: Conductive bonding layer | |
| 31: First conductive member | 311: Body portion | |
| 312: First bonding portion | 313: First coupling portion | |
| 314: Second bonding portion | 315: Second coupling portion | |
| 32: Second conductive member | 321: Body portion | |
| 322: Third bonding portion | 323: Third coupling portion | |
| 324: Fourth bonding portion | 325: Fourth coupling portion | |
| 326: Intermediate portion | 327: Horizontal beam portion | |
| 41 to 45, 47, 48: First wire to Fifth wire, Seventh wire, Eighth wire | | |
| 50: Sealing resin | 51: Top surface | 52: Bottom surface |
| 53: First side surface | 54: Second side surface | 55: Recess |
| 61: First wiring | 611: First mounting layer | 612: First metal layer |
| 613: First gate wiring layer | 614: First detection wiring layer | |
| 615: First temperature detection wiring layer | | |
| 616: Second detection wiring layer | 62: Second wiring layer | |
| 621: Second mounting layer | 622: Second metal layer | |
| 623: Second gate wiring layer | 624: Third detection wiring layer | |
| 625: Second temperature detection wiring layer | | |
| 626: Fourth detection wiring layer | 63: Sleeve | 631: End surface |
| 68: Second bonding layer | 69: Third bonding layer | |
| 70: Housing | 70A: Obverse surface | |
| 70B: Reverse surface | 701 to 704: First surface to Fourth surface | |
| 71: Inlet | 72: Outlet | 73: Hollow portion |
| 731: First peripheral surface | 732: Second peripheral surface | |
| 74: Receiving portion | 741: Intermediate surface | |
| 742: Inner circumferential surface | 742A to 742C: First area to Third area | |
| 75: Recess | 76: Heat dissipation body | |
| 761 to 763: First heat dissipation body to Third heat dissipation body | | |
| 77: Attachment portion | | |
| 771 to 773: First attachment portion to Third attachment portion | | |
| 81: Capacitor | 81A to 81C: First capacitor to Third capacitor | |
| 811: First terminal | 812: Second terminal | 82: Current sensor |
| 821: Third terminal | 822: Fourth terminal | 83: Busbar |
| 84: Attachment member | 85: Wiring board | 86: Exciter |
| 861: Fifth terminal | 862: Sixth terminal | |
| z: First direction | x: Second direction | y: Third direction |

1. A semiconductor module comprising:
a cooler;
a plurality of semiconductor devices mounted on the cooler; and
a capacitor electrically connected to each of the plurality of semiconductor devices and housed in the cooler,
wherein the cooler includes a housing having a receiving portion and a hollow portion that is located around and outwardly surrounds the receiving portion as viewed in a first direction,
the housing has a first surface, a second surface, and a third surface on which the plurality of semiconductor devices are respectively mounted,
each of the first surface, the second surface, and the third surface faces away from the receiving portion with respect to the hollow portion in a direction orthogonal to the first direction,
the first surface, the second surface and the third surface each have a different normal direction, and
at least a part of the capacitor is housed in the receiving portion.

2. The semiconductor module according to claim 1, wherein the housing has an obverse surface facing one side in the first direction, and
the receiving portion has an opening on the obverse surface.

3. The semiconductor module according to claim 2, wherein the second surface is located between the first surface and the third surface,
the first surface and the second surface are adjacent to each other, and
the first surface and the second surface form an internal angle that is equal to or greater than 90 degrees as viewed in the first direction.

4. The semiconductor module according to claim 3, wherein the first surface and the third surface face away from each other in a direction orthogonal to the first direction.

5. The semiconductor module according to claim 3, wherein the housing has an inner circumferential surface that faces a direction orthogonal to the first direction and defines the receiving portion, and
the capacitor is in contact with the inner circumferential surface.

6. The semiconductor module according to claim 5, wherein the inner circumferential surface includes a first area facing away from the first surface in a direction orthogonal to the first direction and a second area facing away from the second surface in a direction orthogonal to the first direction, and
the capacitor is in contact with each of the first area and the second area.

7. The semiconductor module according to claim 6, wherein the capacitor includes a first capacitor and a second capacitor separated from each other,
the first capacitor is in contact with the first area, and
the second capacitor is in contact with the second area.

8. The semiconductor module according to claim 5, wherein the entire capacitor is housed in the receiving portion.

9. The semiconductor module according to claim 5, wherein the housing has an inlet and an outlet, each communicating with the hollow portion, and
the inlet is located closer to the first surface than the outlet.

10. The semiconductor module according to claim 9, wherein the housing has a fourth surface facing a direction orthogonal to the first direction,
the fourth surface is located an opposite side of the second surface with respect to the first surface, and
the inlet and the outlet are provided on the fourth surface.

11. The semiconductor module according to claim 10, wherein the inlet has a center located closer to the obverse surface than a center of the outlet in the first direction.

12. The semiconductor module according to claim 10, wherein the cooler further includes a plurality of heat dissipation bodies housed in the hollow portion, and
the plurality of heat dissipation bodies respectively overlap with the first surface, the second surface, and the third surface as viewed in a direction orthogonal to the first direction.

13. The semiconductor module according to claim 12, wherein the housing has a first peripheral surface and a second peripheral surface that face each other in a direction orthogonal to the first direction and define the hollow portion,
the second peripheral surface is located between the first peripheral surface and the inner circumferential surface, and
each of the plurality of heat dissipation bodies is connected to the first peripheral surface.

14. The semiconductor module according to claim 13, wherein each of the plurality of heat dissipation bodies is connected to the second peripheral surface.

15. The semiconductor module according to claim 14, wherein the plurality of heat dissipation bodies includes a first heat dissipation body and a second heat dissipation body,
the first heat dissipation body is connected to an area of the first peripheral surface facing away from the first surface in a direction orthogonal to the first direction,
the second heat dissipation body is connected to an area of the second peripheral surface facing away from the second surface in a direction orthogonal to the first direction,
the second heat dissipation body has a surface area greater than a surface area of the first heat dissipation body.

16. The semiconductor module according to claim 10, further comprising a current sensor mounted on the housing,
wherein the current sensor is electrically connected to each of the plurality of semiconductor devices, and
the current sensor is located on one side in the first direction with respect to the receiving portion.

17. The semiconductor module according to claim 12, further comprising an exciter mounted on the housing,
wherein the exciter is electrically connected to the capacitor.

18. A vehicle comprising:
a drive source; and
the semiconductor module according to claim 12,
wherein the semiconductor module is electrically connected to the drive source.
